(19) United States
(12) Patent Application Publication
(10) Pub. No.: US 2026/0157216 A1
(43) Pub. Date: Jun. 4, 2026

(54) SEMICONDUCTOR PACKAGE

(71) Applicant: SAMSUNG ELECTRONICS CO., LTD., Suwon-si (KR)

(72) Inventors: Geunwoo KIM, Suwon-si (KR); Junbae Kim, Suwon-si (KR)

(73) Assignee: SAMSUNG ELECTRONICS CO., LTD., Suwon-si (KR)

(21) Appl. No.: 19/376,357

(22) Filed: Oct. 31, 2025

(30) Foreign Application Priority Data
Dec. 2, 2024 (KR) 10-2024-0176715

(51) Int. Cl. H01L 23/49; H01L 23/00; H01L 23/31; H01L 23/498; H01L 25/18; H10D 1/60

(52) U.S. Cl. CPC H10W 72/50; H10D 1/60; H10W 74/117; H10W 90/00; H10W 90/701; H10W 90/754

(57) ABSTRACT

A semiconductor package may comprise a package substrate, a semiconductor chip on the package substrate, conductive wires electrically connected to the semiconductor chip and the package substrate, a sealing member on the package substrate, the semiconductor chip, and the conductive wires; external connection members arranged on a lower surface of the package substrate; a capacitor on at least an upper surface of the sealing member, a first conductive post, and a second conductive post. The capacitor may comprise a lower electrode structure, a dielectric layer, and an upper electrode sequentially stacked. Each of the first and second conductive posts may be electrically connected to at least one of the external connection members. The first conductive post may contact the lower electrode structure. The second conductive post may contact the upper electrode.

### CROSS-REFERENCE TO RELATED APPLICATION

This application claims priority under 35 USC § 119 to Korean Patent Application No. 10-2024-0176715, filed on Dec. 2, 2024, in the Korean Intellectual Property Office, the disclosure of which is incorporated by reference herein in its entirety.

### BACKGROUND

### 1. Field

One or more example embodiments may relate to a semiconductor package. Particularly, one or more example embodiments may relate to a semiconductor package in which electromagnetic waves are shielded and power/signal noise is reduced.

### 2. Description of Related Art

There are many limiting factors such as noise and signal delay in the high-speed operation of semiconductor chips. Recently, the number of simultaneously transmitted signals in the semiconductor chip may be increased, and a signal transmission speed in the semiconductor chip may also be continuously increased. Accordingly, a parasitic inductance component of a semiconductor package in which the semiconductor chip is mounted may be increased, and thus a significant amount of power/signal noise in the semiconductor package may be generated. The semiconductor chip included in the semiconductor package may also be damaged by electromagnetic interference (EMI) caused by electromagnetic waves introduced from outside the semiconductor package. Also, the functioning of a wireless system including an electronic product comprising the semiconductor package may be negatively affected by the electromagnetic waves emitted from the semiconductor package.

### SUMMARY

One or more example embodiments of the disclosure may provide a semiconductor package in which electromagnetic waves may be shielded and power/ground noise may be reduced.

One or more example embodiments of the disclosure may provide a semiconductor package. The semiconductor package may comprise a package substrate; a semiconductor chip on the package substrate; conductive wires electrically connected with the semiconductor chip and the package substrate; a sealing member on the package substrate to cover the semiconductor chip and the conductive wires; external connection members on a lower surface of the package substrate; a capacitor on at least an upper surface of the sealing member, and the capacitor including a lower electrode structure, a dielectric layer, and an upper electrode sequentially stacked; a first conductive post electrically connected to at least one of the external connection members, the first conductive post in the sealing member, and an upper surface of the first conductive post in contact with the lower electrode structure; and a second conductive post electrically connected to at least one of the external connection members, the second conductive post in the sealing member and spaced apart from the lower electrode structure, an upper surface of the second conductive post in contact with the upper electrode. At least one of the first conductive post and the second conductive post may be spaced apart from the conductive wires.

One or more example embodiments of the disclosure may provide a semiconductor package. The semiconductor package may comprise a package substrate including a first pad pattern, a second pad pattern, and a third pad pattern on an upper surface thereof; a semiconductor chip on the package substrate, and an upper surface of the semiconductor chip including a fourth pad pattern; a conductive wire electrically connected with the first pad pattern and the fourth pad pattern; a sealing member on the package substrate to cover the semiconductor chip and the conductive wire; a capacitor including at least a lower electrode structure, a dielectric layer and an upper electrode sequentially stacked on an upper surface of the sealing member; a first conductive post passing through the sealing member and being spaced apart from the semiconductor chip, and the first conductive post extending upwardly from the second pad pattern and contacting the lower electrode structure; and a second conductive post passing through the sealing member and being spaced apart from the semiconductor chip, and the second conductive post extending upwardly from the third pad pattern and contacting the upper electrode and being spaced apart from the lower electrode structure. At least one of the first conductive post and the second conductive post may be spaced apart from the conductive wire.

One or more example embodiments of the disclosure may provide a semiconductor package. The semiconductor package may comprise a package substrate including a first pad pattern and a second pad pattern on an upper surface thereof; a semiconductor chip on the package substrate, and an upper surface of the semiconductor chip including a third pad pattern and a fourth pad pattern; a conductive wire electrically connected to the first pad pattern and the third pad pattern; a sealing member on the package substrate, the semiconductor chip, and the conductive wire; a capacitor comprising a lower electrode structure, a dielectric layer, and an upper electrode sequentially stacked on at least an upper surface of the sealing member; a first conductive post in the sealing member and spaced apart from the semiconductor chip, the first conductive post extending upwardly from the second pad pattern and contacting the lower electrode structure; and a second conductive post in the sealing member, the second conductive post extending upwardly from the fourth pad pattern of the semiconductor chip and contacting the upper electrode spaced apart from the lower electrode structure. At least one of the first conductive post and the second conductive post may be spaced apart from the conductive wire.

According to one or more example embodiments, the capacitor may be arranged on at least an upper surface of the semiconductor package. Because of the capacitor's proximity to circuit patterns of the semiconductor chip, a parasitic inductance there among may be greatly substantially reduced. Therefore, the Signal Integrity (SI) and Power Integrity (PI) of the semiconductor package may be improved. Furthermore, because electromagnetic waves may be shielded by one electrode of the capacitor, the prevalence and severity of defects of the semiconductor chip and electronic products including the semiconductor chip due to the electromagnetic waves may be reduced.

However, the effects of the disclosure are not limited to those described above, and may be variously expanded within the scope of the disclosure.

### BRIEF DESCRIPTION OF DRAWINGS

Various one or more example embodiments will be more clearly understood from the following detailed description taken in conjunction with the accompanying drawings. FIGS. 1 to 38 represent various non-limiting, one or more example embodiments as described herein.

FIG. 1 is a cross-sectional view illustrating a semiconductor package according to one or more example embodiments;

FIG. 2 is a plan view illustrating a semiconductor package according to one or more example embodiments;

FIG. 3 is a plan view illustrating a semiconductor package according to one or more example embodiments;

FIG. 4 is a cross-sectional view illustrating a semiconductor package according to one or more example embodiments;

FIGS. 5 and 6 are cross-sectional views illustrating semiconductor packages according to one or more example embodiments, respectively;

FIG. 7 is a cross-sectional view illustrating a semiconductor package according to one or more example embodiments;

FIG. 8 is a cross-sectional view illustrating a semiconductor package according to one or more example embodiments;

FIG. 9 is a cross-sectional view illustrating a semiconductor package according to one or more example embodiments;

FIGS. 10 to 19 are cross-sectional views and plan views illustrating a method of manufacturing a semiconductor package according to one or more example embodiments;

FIG. 20 is a cross-sectional view illustrating a semiconductor package according to one or more example embodiments;

FIG. 21 is a plan view illustrating a semiconductor package according to one or more example embodiments;

FIG. 22 is a plan view illustrating a semiconductor package according to one or more example embodiments;

FIG. 23 is a cross-sectional view illustrating a semiconductor package according to one or more example embodiments;

FIG. 24 is a cross-sectional view illustrating a semiconductor package according to one or more example embodiments;

FIG. 25 is a cross-sectional view illustrating a semiconductor package according to one or more example embodiments;

FIG. 26 is a cross-sectional view illustrating a semiconductor package according to one or more example embodiments;

FIG. 27 is a cross-sectional view illustrating a semiconductor package according to one or more example embodiments;

FIG. 29 is a cross-sectional view illustrating a semiconductor package according to one or more example embodiments;

FIG. 30 is a cross-sectional view illustrating a semiconductor package according to one or more example embodiments;

FIGS. 31 to 33 are cross-sectional views illustrating a method of manufacturing a semiconductor package according to one or more example embodiments;

FIG. 34 is a cross-sectional view illustrating a semiconductor package according to one or more example embodiments;

FIG. 35 is a cross-sectional view illustrating a semiconductor package according to one or more example embodiments;

FIG. 36 is a cross-sectional view illustrating a semiconductor package according to one or more example embodiments; and

FIG. 37 is a cross-sectional view illustrating a semiconductor package according to one or more example embodiments; and

FIG. 38 is a cross-sectional view illustrating a semiconductor package according to one or more example embodiments.

### DETAILED DESCRIPTION

Hereinafter, various one or more example embodiments will be described in detail with reference to the accompanying drawings. Each of the embodiments provided herein is not excluded from being associated with one or more features of another example or another embodiment also provided herein or not provided herein but consistent with the disclosure.

It is to be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” and “at least one of a, b, or c” should be understood as including only a, only b, only c, both a and b, both a and c, both b and c, or all of a, b, and c.

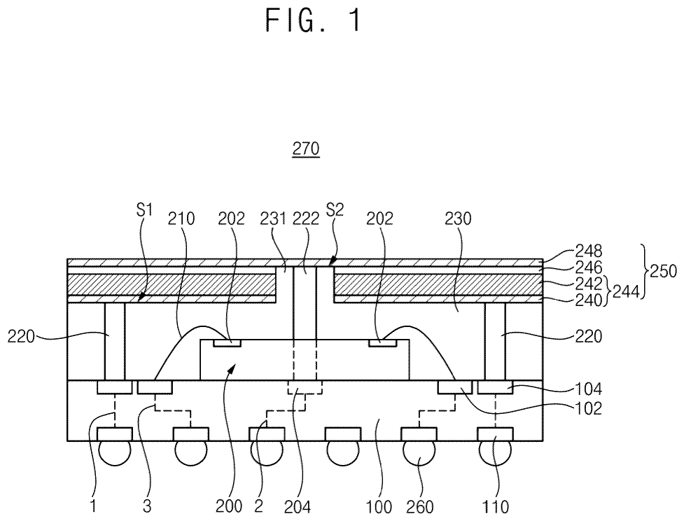

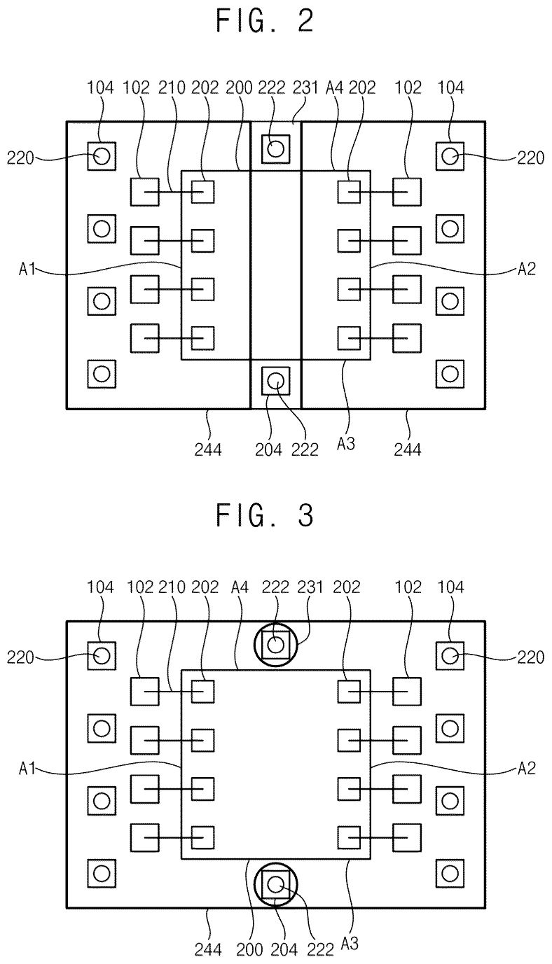

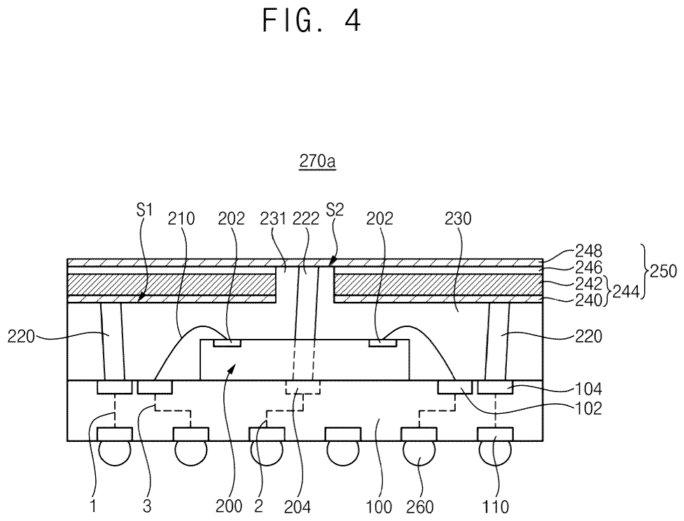

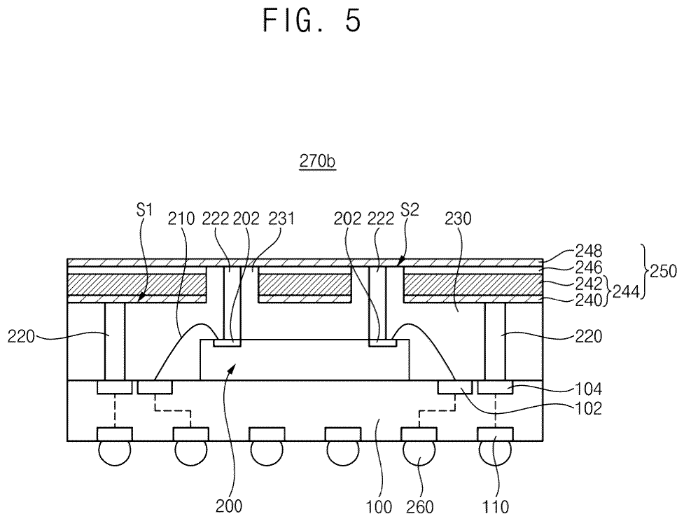

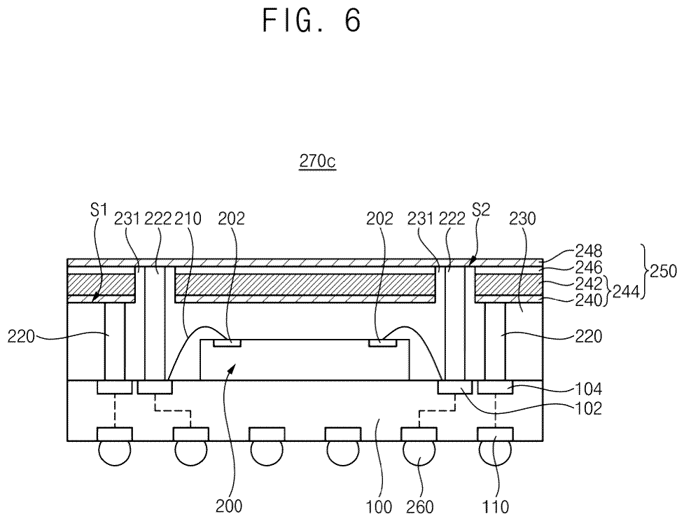

FIG. 1 is a cross-sectional view illustrating a semiconductor package according to one or more example embodiments. FIG. 2 is a plan view illustrating a semiconductor package according to one or more example embodiments. FIG. 3 is a plan view illustrating a semiconductor package according to one or more example embodiments. FIG. 4 is a cross-sectional view illustrating a semiconductor package according to one or more example embodiments. FIGS. 5 and 6 are cross-sectional views illustrating semiconductor packages according to one or more example embodiments, respectively.

To avoid complexity of the drawings, some elements (e.g., upper electrodes) may be omitted in the plan views of FIGS. 2 and 3.

Referring to FIG. 1, a semiconductor package 270 may include a package substrate 100, a semiconductor chip 200, a conductive wire 210, a sealing member 230, a first conductive post 220, a second conductive post 222 and a capacitor 250. The capacitor 250 may include a lower electrode structure 244, a dielectric layer 246 and an upper electrode 248 sequentially stacked.

The package substrate 100 may have a first surface and a second surface facing each other. The package substrate 100 may be a printed circuit board (PCB). Alternately, the package substrate 100 may be, for example, a silicon interposer or a rewiring interposer. The package substrate 100 may be a multilayer circuit board comprising various internal wirings therein. The internal wirings included in the package substrate 100 may include, for example, power wiring, signal wiring, ground wiring, etc.

Pad patterns 102, 104 and 204 may be arranged on the first surface (e.g., an upper surface) of the package substrate 100. In one or more example embodiments, first pad patterns 102 electrically connected to the semiconductor chip 200, second pad patterns 104 electrically connected to the first conductive post 220, and third pad patterns 204 electrically connected to the second conductive post 222 may be arranged on the first surface of the package substrate 100.

Each of the first pad patterns 102 may be electrically connected, respectively, to a third wiring 3, which may be one of the internal wirings of the package substrate 100, such as the power wiring, the signal wiring, the ground wiring, etc. Each of the second pad patterns 104 may be electrically connected, respectively, to a first wiring 1, which may be one of the internal wirings of the package substrate 100, such as the power wiring, the ground wiring, etc. Each of the third pad patterns 204 may be electrically connected, respectively, to a second wirings 2, which may be one of the internal wirings of the package substrate 100 and may not be connected to the second pad pattern 104. For example, the third wiring 3 may include a power wiring or a ground wiring that is not connected to the second pad pattern 104.

Lower bonding pads 110 may be arranged on the second surface (i.e., the lower surface) of the package substrate 100.

The semiconductor chip 200 may be disposed on the first surface of the package substrate 100. The semiconductor chip 200 may be formed by individualizing semiconductor dies formed on a wafer by a semiconductor manufacturing process.

Circuit patterns may be formed on the upper surface of the semiconductor chip 200. The semiconductor chip 200 may be configured so that a surface on which the circuit patterns are formed may be positioned upward.

Fourth pad patterns 202 may be arranged on the upper surface of the semiconductor chip 200, and the fourth pad patterns 202 may be electrically connected to the circuit patterns and configured to input/output external signals. In one or more example embodiments, the fourth pad patterns 202 may be connected to the conductive wire 210. Each of the fourth pad patterns 202 may be electrically connected to a power wiring, a signal wiring, and/or a ground wiring in the package substrate 100.

The conductive wire 210 may electrically connect the circuit patterns of the semiconductor chip 200 and the package substrate 100. The conductive wire 210 may connect one of the first pad patterns 102 and one of the fourth pad patterns 202 to each other. The conductive wire 210 may extend from one of the first pad patterns 102 to one of the fourth pad patterns 202.

The sealing member 230, which may be a sealing layer, in the package substrate 100 may be formed on the semiconductor chip 200 and the conductive wire 210. In one or more example embodiments, the sealing member 230 may entirely cover an upper surface of the package substrate 100 except for a portion thereof on which the semiconductor chip 200 is disposed.

In one or more example embodiments, the sealing member 230 may cover four sidewalls and the upper surface of the semiconductor chip 200, and thus the sealing member 230 may include four outer sidewalls and an upper surface.

An upper portion of the sealing member 230 may include a protrusion 231 that protrudes upward from a first upper surface S1 of a recessed portion of the sealing member 230. The recessed portion may comprise the upper portion of the sealing member 230 except for the protrusion 231. In the sealing member 230, the first upper surface S1 may refer to an upper surface of the recessed portion, and a second upper surface S2 may refer to an upper surface of the protrusion 231. Each of the first and second upper surfaces S1 and S2 may be substantially flat. The protrusion 231 of the sealing member 230 may be disposed to overlap at least a portion of the upper surface of the semiconductor chip 200. The protrusion 231 may face at least a portion of an upper surface of the semiconductor chip 200.

In one or more example embodiments, the sealing member 230 may include an epoxy mold compound (EMC).

The capacitor 250 may be disposed on the upper surface of the sealing member 230, and the capacitor 250 may cover at least the upper surface of the sealing member 230.

In one or more example embodiments, a stacked structure of the lower electrode structure 244 and the dielectric layer 246 may be disposed on the first upper surface S1 of the sealing member 230 and the first conductive post 220. The stacked structure of the lower electrode structure 244 and the dielectric layer 246 may not be formed on the second upper surface S2 of the sealing member 230.

The stacked structure of the lower electrode structure 244 and the dielectric layer 246 may include a portion spaced apart by the protrusion 231 of the sealing member 230. The stacked structure of the lower electrode structure 244 and the dielectric layer 246 may contact a sidewall of the protrusion 231, and the stacked structure may surround the sidewall of the protrusion 231. The stacked structure of the lower electrode structure 244 and the dielectric layer 246 may cover an entire first upper surface S1 of the sealing member 230, except for the upper surface of the protrusion 231 of the sealing member 230.

Depending on a shape of the protrusion 231, the lower electrode structures 244 may be separated from each other by interposing the protrusion 231, or the lower electrode structure 244 may by connected to each other at a location other than the protrusion 231.

In one or more example embodiments, as shown in FIG. 2, the lower electrode structures 244 may be separated into at least two on the upper surface of the sealing member 230. For example, the protrusion 231 of the sealing member 230 may have a line shape extending in one direction.

In one or more example embodiments, as shown in FIG. 3, the lower electrode structure 244 may be connected to each other at a location other than the protrusion 231 to form one body. A plurality of protrusions 231 may be arranged to be spaced apart from each other in one direction. For example, each of the protrusions 231 may have a pillar shape. In this case, the lower electrode structure 244 may include through holes, and the protrusions 231 may be formed in the through holes, respectively.

In one or more example embodiments, an upper surface of the stacked structure of the lower electrode structure 244 and the dielectric layer 246 and the second upper surface S2 of the sealing member 230 may be substantially coplanar with each other. Therefore, the upper surface of the stacked structure of the lower electrode structure 244 and the dielectric layer 246 and the second upper surface S2 of the sealing member 230 may be flat.

The upper electrode 248 may be disposed on the dielectric layer 246, the second upper surface S2 of the sealing member 230 and the second conductive post 222, and the upper electrode 248 may cover the surface of the dielectric layer 246, the second upper surface S2 of the sealing member 230 and the upper surface of the second conductive post 222. Therefore, the upper surface of the semiconductor package 270 may be covered with only the upper electrode 248. Only the upper electrode 248 may be exposed on the upper surface of the semiconductor package 270.

In one or more example embodiments, the upper electrode 248 may face the entire upper surface of the package substrate 100. For example, an area of the lower surface of the upper electrode 248 and an area of the upper surface of the package substrate 100 may be substantially the same. In one or more example embodiments, the upper electrode 248 may partially face the upper surface of the package substrate 100.

In the capacitor 250, a remaining portion of the upper electrode 248 except for a portion contacting the protrusion 231 of the sealing member 230 and the upper surface of the second conductive post 222 may face the lower electrode structure 244. Therefore, in the capacitor 250, a surface area where the lower electrode structure 244 and the upper electrode 248 face each other may be increased to be similar to the area of the upper surface of the package substrate 100. In one or more example embodiments, the surface area where the lower electrode structure 244 and the upper electrode 248 in the capacitor 250 face each other may be about 80% or more of an area of the upper surface of the package substrate 100.

In the semiconductor package 270, the capacitor 250 may not be placed on outer sidewalls of the sealing member 230 formed on the package substrate 100. In the semiconductor package 270, the sealing member 230 and the lower electrode structure 244, the dielectric layer 246, and the upper electrode 248 of the capacitor 250 may be exposed together on outer sidewalls of a structure placed on the package substrate 100. That is, the package substrate 100, the sealing member 230, the lower electrode structure 244, the dielectric layer 246, and the upper electrode 248 may be exposed together on at least one sidewall of the semiconductor package 270.

Each of the lower electrode structure 244 and the upper electrode 248 may include a metal.

The lower electrode structure 244 may include a first metal layer 240 and a second metal layer 242. The first metal layer 240 may include a seed metal layer for forming the second metal layer 242. The second metal layer 242 may include a material having electrical conductivity higher than that of the first metal layer 240. In one or more example embodiments, the first metal layer 240 may include stainless steel (SUS), and the second metal layer 242 may include copper.

The upper electrode 248 may include a third metal layer. The third metal layer may be disposed on an outermost surface of the semiconductor package 270, and the third metal layer may serve as a capping layer of the semiconductor package 270. In one or more example embodiments, the third metal layer may include stainless steel SUS.

The dielectric layer 246 may include an inorganic layer. In one or more example embodiments, the dielectric layer 246 may include silicon oxide, silicon nitride, silicon oxynitride, titanium oxide, tantalum oxide, hafnium oxide, zirconium oxide, or polyimide PI.

A minimum thickness in a vertical direction of the sealing member 230 positioned on the upper surface of the semiconductor chip 200 may be substantially equal to a minimum separation distance between the semiconductor chip 200 and the capacitor 250. In one or more example embodiments, the minimum thickness in the vertical direction of the sealing member 230 positioned on the upper surface of the semiconductor chip 200 may be in range of about 1 μm to about 10 μm. For example, the minimum thickness in the vertical direction of the sealing member 230 positioned on the upper surface of the semiconductor chip 200 may be about 5 μm to about 6 μm. In this way, because the minimum separation distance between the semiconductor chip 200 and the capacitor 250 is very small, e.g., about 5 μm to about 6 μm, an effect of reducing an inductance may be increased by the capacitor 250. In addition, as the surface area where the lower electrode structure 244 and the upper electrode 248 of the capacitor 250 face each other increases, a capacitance of the capacitor 250 may increase. Accordingly, the signal integrity (SI) and power integrity (PI) in the semiconductor package 270 may be improved, and signal noise and power noise in the semiconductor package 270 may be reduced. Particularly, the signal integrity and the power integrity in a semiconductor package that operates at a high frequency may be improved.

One of the lower electrode structure 244 and the upper electrode 248 may be applied with a power supply voltage, and the other may be grounded. For example, the lower electrode structure 244 may be applied with the power supply voltage, and the upper electrode 248 may be grounded. In the following description, the lower electrode structure 244 may be applied with the power supply voltage, and the upper electrode 248 may be grounded. However, the one or more example embodiments are not limited thereto, for example, the lower electrode structure 244 may be grounded, and the upper electrode 248 may be applied with a power supply voltage.

The first conductive post 220 may contact the lower electrode structure 244. The first conductive post 220 may extend from a lower surface of the lower electrode structure 244 to the upper surface of the package substrate 100 passing through the sealing member 230, and may be electrically connected to the power wiring among the internal wirings of the package substrate 100. A lower surface of the first conductive post 220 may contact the second pad pattern 104 of the package substrate 100. The first conductive post 220 may electrically connect one of the second pad patterns 104 and the lower electrode structure 244 of the capacitor 250 to each other.

The second conductive post 222 may be spaced apart from the lower electrode structure 244, and may contact the upper electrode 248. The second conductive post 222 may extend form a lower surface of the upper electrode 248 to the upper surface of the package substrate 100 passing through the sealing member 230. The second conductive post 222 may be electrically connected to the ground wiring among the internal wirings of the package substrate 100. A lower surface of the second conductive post 222 may contact the third pad pattern 204 of the package substrate. The second conductive post 222 may connect one of the third pad patterns 204 and the upper electrode 248 of the capacitor 250 to each other. In one or more example embodiments, the second conductive post 222 may pass through the lower electrode structure 244. The first and second conductive posts 220 and 222 may be arranged to be spaced apart from outer sidewalls of the semiconductor chip 200. The semiconductor chip 200 may include a first sidewall A1 and a second sidewall A2 facing each other in a first direction, and a third sidewall A3 and a fourth sidewall A4 facing each other in a second direction perpendicular to the first direction. In one or more example embodiments, the first conductive posts 220 may be arranged to be spaced apart from the first side A1 and the second side A2 of the semiconductor chip 200, respectively. The second conductive posts 222 may be arranged to be spaced apart from the third side A3 and the fourth side A4 of the semiconductor chip 200, respectively. However, positions of the first and second conductive posts 220 and 222 may not be limited thereto.

Because the third pad pattern 204 and the second conductive posts 222 are positioned adjacent to a rear of the semiconductor chip 200, portions of the third pad pattern 204 and the second conductive posts 222 may not be visible in each cross-sectional view. Therefore, portions of the third pad pattern 204 and the second conductive posts 222 are indicated by a dotted line in each cross-sectional view.

An external connection member 260 may be arranged on the lower bonding pad 110 of the second surface of the package substrate 100. The external connection member 260 may be a conductive bump. The external connection member 260 may be electrically connected to each pad pattern of the package substrate 100. In addition, the external connection member 260 may be electrically connected to each pad pattern of the semiconductor chip 200.

Accordingly, signals may be input/output from outside of the semiconductor package 270 to the package substrate 100 and the semiconductor chip 200 through the external connection member 260.

The first conductive post 220 may penetrate downwardly from an upper surface of the recessed portion of the sealing member 230. The first conductive post 220 may extend upward from the upper surface of one of the second pad patterns 104 to the lower surface of the lower electrode structure 244. The upper surface of the first conductive post 220 may contact the lower surface of the lower electrode structure 244. The lower surface of the first conductive post 222 may contact the upper surface of the package substrate 100. A plurality of first conductive posts 220 may be arranged to be spaced apart from each other.

In one or more example embodiments, the first conductive posts 220 may be spaced apart from the conductive wire 210, and closer to an edge of the package substrate 100 than the conductive wire 210. In addition, the second conductive posts 222 may be spaced apart from the conductive wire 210, and closer to another edge of the package substrate 100 than another conductive wire 210.

Each of the first conductive posts 220 may electrically connect the second pad pattern 104 to the power wiring within the package substrate 100 and the lower electrode structure 244. Therefore, a power voltage may be applied to the lower electrode structure 244 through the external connection member 260, the internal wirings of the package substrate 100, the second pad pattern 104 and the first conductive post 220. That is, the first conductive post 220 may be electrically connected to one of the external connecting members 260.

The second conductive post 222 may downwardly extend from the upper surface of the protrusion 231 of the sealing member 230. The second conductive post 222 may extend upwardly from the upper surface of one of the third pad patterns 204 to the lower surface of the upper electrode 248. The upper surface of the second conductive post 222 may contact the lower surface of the upper electrode 248. The lower surface of the second conductive post 222 may contact the upper surface of the package substrate 100. A plurality of second conductive posts 222 may be arranged to be spaced apart from each other.

The second conductive post 222 may be extended from a lower surface of the upper electrode 248 to the third pad pattern 204 of the semiconductor chip 200 while being insulated from the lower electrode structure 244. The second conductive post 222 may electrically connect the upper electrode 248 and the third pad pattern 204 being electrically connected to the ground wiring within the package substrate 100. Accordingly, the upper electrode 248 may be grounded through the second conductive post 222, the third pad pattern 204, the internal wiring of the package substrate 100 and the external connection member 260. That is, the second conductive post 222 may be electrically connected to one of the external connection members 260. The external connection member 260 connected to the second conductive post 222 may have a different voltage to it than the external connection member 260 connected to the first conductive post 220. The first conductive post 220 and the second conductive post 222 may be connected to different external connection members, respectively.

The first and second conductive posts 220 and 222 may include, e.g., copper (Cu), aluminum (Al), tin (Sn), nickel (Ni), gold (Au), platinum (Pt), or an alloy thereof. The first and second conductive posts 220 and 222 may include the same metal material.

In one or more example embodiments, as shown in FIG. 1, in the semiconductor package 270, the first and second conductive posts 220 and 222 may extend in a vertical direction with respect to the upper surface (i.e., a flat surface in a horizontal direction) of the package substrate 100.

In one or more example embodiments, as shown in FIG. 4, in the semiconductor package 270a, at least one of the first and second conductive posts 220 and 222 may extend obliquely from the upper surface of the package substrate 100 with a non-vertical slope. For example, at least one of the first and second conductive posts 220 and 222 may have a slope greater than 60 degrees and less than 90 degrees with respect to the upper surface of the package substrate 100. Although FIG. 4 illustrates that all of the first and second conductive posts 220 and 222 have the non-vertical slope, the disclosure is not limited thereto. For example, only some of the first and second conductive posts 220 and 222 may obliquely extend to have the non-vertical slope. In FIG. 4, the first and second conductive posts 220 and 222 are illustrated as having a constant slope, but this is not limited thereto. For example, the first and second conductive posts 220 and 222 may have different slopes, or may have a curved shape or a bent shape at some portions thereof.

The semiconductor package may be implemented in one or more example embodiments by changing at least part of one or more of the pad patterns contacting the lower surfaces of the first and second conductive posts 220 and 222.

In one or more example embodiments, as illustrated in FIG. 5, in the semiconductor package 270b, a separate third pad pattern may not be formed, and the third and fourth pad patterns may be merged. That is, the second conductive post 222 may contact the fourth pad pattern 202 connected to the ground wiring among the fourth pad patterns 202, and the fourth pad pattern 202 also may be electrically connected to the first pad pattern 102 through the conductive wire 210. Accordingly, the upper electrode 248 may be grounded through the second conductive post 222, the fourth pad pattern 202, the conductive wire 210, the first pad pattern 102, the internal wiring of the package substrate 100 and the external connecting member 260.

In one or more example embodiments, as shown in FIG. 6, in the semiconductor package 270c, a separate third pad pattern may not be formed, and the first and third pad patterns may be merged. That is, the second conductive post 222 may contact the first pad pattern 102 connected to the ground wiring among the first pad patterns 102. In addition, the first pad pattern 102 may be electrically connected to the fourth pad pattern 202 through the conductive wire 210. The upper electrode 248 may be grounded through the second conductive post 222, the first pad pattern 102, the internal wiring of the package substrate 100 and the external connection member 260.

As described above, the semiconductor package may have the capacitor 250 arranged on the upper surface of the sealing member 230. In addition, the power voltage may be applied to the lower electrode structure 244 of the capacitor 250, and the ground voltage may be applied to the upper electrode 248. The semiconductor package may have a high-capacitance capacitor adjacent the semiconductor chip, the signal integrity and the power integrity in the semiconductor package may be improved, and the signal noise and the power noise may be reduced.

Because the upper electrode 248 is grounded, electromagnetic waves applied to the upper electrode 248 may be grounded through the package substrate 100 without affecting the semiconductor chip 200. Therefore, the upper electrode 248 of the capacitor 248 may also serve as a shield layer that shields electromagnetic waves. Defects of semiconductor chips in the semiconductor package and electronic products including semiconductor package due to electromagnetic waves may be decreased.

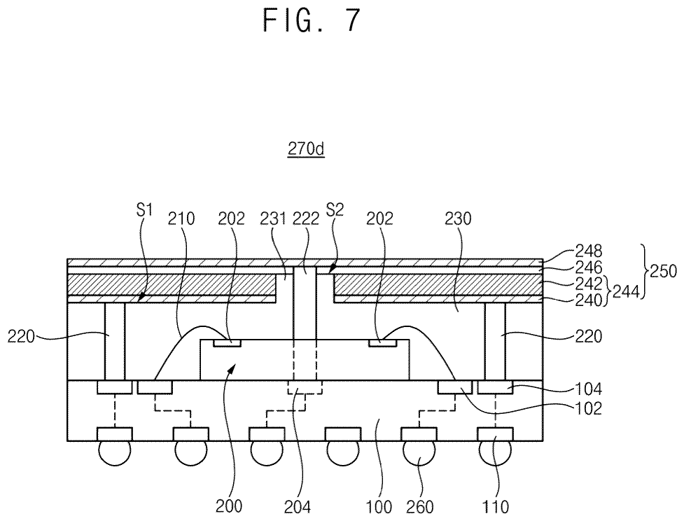

FIG. 7 is a cross-sectional view showing a semiconductor package according to one or more example embodiments.

The semiconductor package 270d shown in FIG. 7 is substantially similar to or substantially identical to the semiconductor package shown in FIG. 1, except for a shape of a dielectric layer.

Referring to FIG. 7, the sealing member 230 may include the protrusion 231 and the recessed portion. An upper surface of the second conductive post 222 may protrude farther from the package substrate 100 than an upper surface (i.e., the second upper surface, S2) of the protrusion 231 of the sealing member 230.

In one or more example embodiments, an upper surface of the lower electrode structure 244 and the upper surface of the protrusion 231 of the sealing member 230 may be substantially coplanar with each other. Therefore, the upper surface of the lower electrode structure 244 and the upper surface of the protrusion of the sealing member 230 may be substantially flat.

The dielectric layer 246 may cover upper surfaces of the lower electrode structure 244 and the protrusion 231 of the sealing member 230. The dielectric layer 246 may not cover the upper surface of the second conductive post 222, and the dielectric layer 246 may contact an upper sidewall of the second conductive post 222.

The upper electrode 248 may cover the dielectric layer 246 and the upper surface of the second conductive post 222.

Therefore, the upper surface of the semiconductor package 270d may be covered by only the upper electrode 248.

The first conductive post 220 may extend from one of the upper surfaces of the second pad patterns 104 of the package substrate 100 to the lower surface of the lower electrode structure 244.

The second conductive post 222 may extend from the third pad pattern 204 of the upper surface of the package substrate 100 to the lower surface of the upper electrode 248 while being insulated from the lower electrode structure 244. Accordingly, the second conductive post 222 may pass through at least the dielectric layer 246 and the protrusion 231 of the sealing member 230.

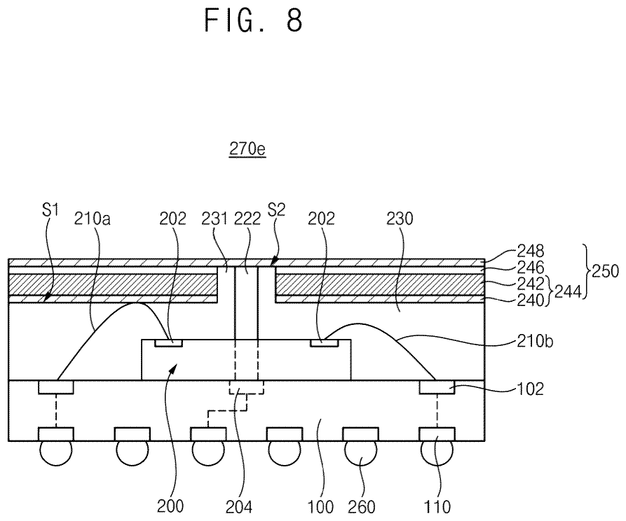

FIG. 8 is a cross-sectional view illustrating a semiconductor package according to one or more example embodiments.

The semiconductor package 270e shown in FIG. 8 may be substantially identical to the semiconductor package shown in FIG. 1, except that the first conductive post 220 and the second pad patterns 104 are not included, and a shape of the conductive wire 210a is different.

Referring to FIG. 8, the first pad patterns 102 for electrically connecting with the semiconductor chip 200 may be arranged on the upper surface of the package substrate 100. In one or more example embodiments, the second pad patterns 104 electrically connected with the first conductive post 220 may not be arranged on the upper surface of the package substrate 100.

The first conductive wire 210a may contact a lower surface of the lower electrode structure 244 of the capacitor 250 while connecting the first pad pattern 102 and the fourth pad pattern 202 to each other. The power voltage may be applied to the lower electrode structure 244 through the first conductive wire 210a.

The first conductive post 220 may not be included in the semiconductor package 270e.

A second conductive wire 210b that connects the first pad pattern 102 and the fourth pad pattern 202 to each other and does not contact the lower surface of the lower electrode structure 244 of the capacitor 250 may be further included in the semiconductor package 270e. The second conductive wire 210b may be substantially identical to the conductive wire described with reference to FIG. 1.

In one or more example embodiments, the semiconductor package may include the first conductive wire 210a, and may further include the second pad patterns 104 that are electrically connected to the first conductive 220 post on the upper surface of the package substrate 100. In addition, the first conductive post 220 contacting the lower electrode structure 244 may also be arranged on the second pad patterns 104.

The second conductive post 222 may be substantially identical to that described with reference to FIG. 1. The second conductive post 222 may contact the upper electrode 248 and the third pad pattern 204.

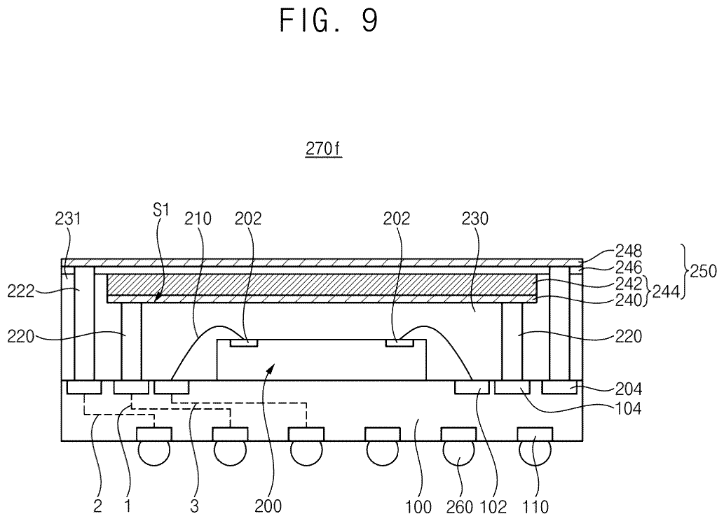

FIG. 9 is a cross-sectional view illustrating a semiconductor package according to one or more example embodiments.

The semiconductor package 270f shown in FIG. 9 is similar to or the same as the semiconductor package shown in FIG. 1, except for the sealing member, pad patterns, and capacitor.

Referring to FIG. 9, first pad patterns 102 for electrically connecting with the semiconductor chip 200, second pad patterns 104 for electrically connecting with the first conductive post 220, and third pad patterns 204 for electrically connecting with the second conductive post 222 may be arranged on the first surface of the package substrate 100.

The second pad pattern 104 and the third pad pattern 204 may be spaced apart from the first pad pattern 102, and the second pad pattern 104 and the third pad pattern 204 may be disposed closer to the edge of the package substrate 100 than the first pad pattern 102. Each of the first pad patterns 102 may be electrically connected to a third wiring 3, which may be, for example, the power wiring, the signal wiring, and/or the ground wiring.

The second pad patterns 104 may be electrically connected to the first wiring 1, which is one of the power wiring and the ground wiring. The third pad patterns 204 may be electrically connected to the second wiring 2, which may be the power wiring or the ground wiring that is not electrically connected to the second pad patterns 104. For example, the second pad patterns 104 may be electrically connected to the power wiring, and the third pad patterns 204 may be electrically connected to the ground wiring.

The fourth pad pattern 202 may be arranged on the upper surface of the semiconductor chip 200 to be connected to a conductive wire 210. The sealing member 230 may be formed on the package substrate 100 to cover the semiconductor chip 200 and the conductive wires 210. The sealing member 230 may have a recessed portion for forming a lower electrode structure 244 of the capacitor. A bottom surface of the recessed portion of the sealing member 230 may be substantially flat. A portion other than the recessed portion of the sealing member 230 may be a protrusion 231.

The lower electrode structure 244 of the capacitor 250 may be disposed inside the recessed portion of the sealing member 230.

In one or more example embodiments, the lower electrode structure 244 may be arranged to overlap at least the upper portions of the semiconductor chip 200, the first pad pattern 102, and the second pad pattern 104. In one or more example embodiments, a sidewall of the lower electrode structure 244 may be covered by the sealing member 230. Therefore, the lower electrode structure 244 may not be exposed at outer sidewalls of the semiconductor package 270f.

The dielectric layer 246 and the upper electrode 248 of the capacitor 250 may be stacked on an upper surface of the protrusion 231 of the sealing member 230 and an upper surface of the lower electrode structure 244.

The upper surface of the semiconductor package 270f may be covered with only the upper electrode 248. Only the upper electrode 248 may be exposed on the upper surface of the semiconductor package 270f. The upper electrode 248 may overlap, in plan view, an entirety of the upper surface of the package substrate 100. In one or more example embodiments, the upper electrode 248 may be disposed to overlap, in plan view, the entirety of the upper surface of the package substrate 100.

The first conductive post 220 may extend through the sealing member 230 to connect one of the second pad patterns 104 to the lower electrode structure 244 of the capacitor 250. The first conductive post 220 may extend upward from an upper surface of one of the second pad patterns 104 to a lower surface of the lower electrode structure 244. A plurality of first conductive posts 220 may be spaced apart from each other.

The second conductive post 222 may extend upward from the third pad pattern 204 to a lower surface of the upper electrode 248 while being insulated from the lower electrode structure 244. The second conductive post 222 may extend through the sealing member 230 downwardly from the upper surface of the protrusion 231 to connect one of the third pad patterns 204 to the upper electrode 248 of the capacitor 250. The second conductive post 222 may be spaced apart from an outer sidewall of the lower electrode structure 244.

In one or more example embodiments, the dielectric layer 246 of the capacitor 250 may be arranged within the recessed portion of the sealing member 230, and thus the dielectric layer 246 may be disposed only on the lower electrode structure 244.

As shown in FIG. 9, the second conductive post 222 may not contact the pad patterns 202 formed on the semiconductor chip 200.

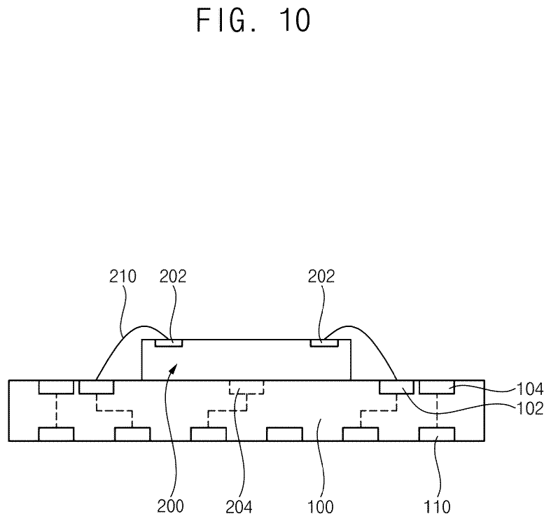

FIGS. 10 to 19 are cross-sectional views and plan views illustrating a method of manufacturing a semiconductor package according to one or more example embodiments.

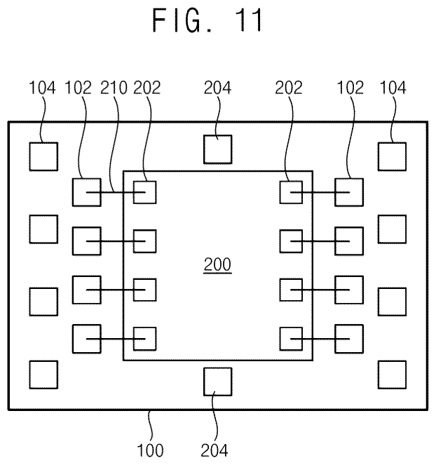

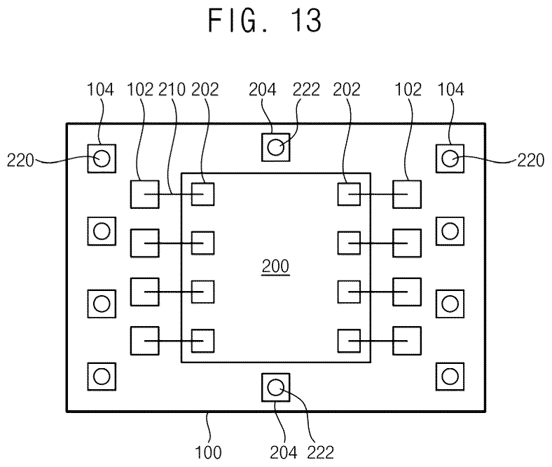

FIGS. 10, 12, 14 to 19 are cross-sectional views, and FIGS. 11 and 13 are plan views. Referring to FIGS. 10 to 19, a method for manufacturing a semiconductor package shown in FIG. 1 is mainly described.

Referring to FIGS. 10 and 11, a semiconductor chip 200 may be placed on a first surface of a package substrate 100.

In one or more example embodiments, first pad patterns 102 for electrically connecting with the semiconductor chip 200, second pad patterns 104 for electrically connecting with the first conductive post 220, and third pad patterns 204 for electrically connecting with the second conductive post 222 may be disposed on the first surface of the package substrate 100. In each cross-sectional view, because the third pad pattern 204 is positioned adjacent a rear of the semiconductor chip 200, the third pad pattern 204 is indicated by a dotted line.

The pad patterns formed on the first surface of the package substrate 100 may not be limited thereto. In one or more example embodiments, the first surface of the package substrate 100 may not include the second pad patterns 104.

In one or more example embodiments, a wafer on which semiconductor chips 200 is formed may be sawed to form individualized semiconductor chips 200, and each of the individualized semiconductor chips 200 may be placed on the package substrate 100. The semiconductor chip 200 may be disposed so that a surface on which the circuit patterns are formed may be positioned upward.

In one or more example embodiments, fourth pad patterns 202 for inputting/outputting external signals may be arranged on the semiconductor chip 200. The fourth pad patterns 202 may be pads for being connected to the conductive wire 210. However, the pad patterns formed on the semiconductor chip 200 may not be limited thereto.

The pad patterns 202 and 204 of the semiconductor chip 200 and the pad patterns 102 and 104 of the package substrate 100 may be electrically connected to each other by the conductive wire 210 formed by a wire bonding process.

Particularly, the conductive wire 210 may connect one of the fourth pad patterns 202 to one of the first pad patterns 102. The conductive wire 210 may extend from one of the fourth pad patterns 202 to one of the first pad patterns 102. Accordingly, the conductive wire 210 may electrically connect the circuit patterns in the semiconductor chip 200 and the wirings in the package substrate 100.

In one or more example embodiments, as shown in FIG. 8, the first conductive wire 210a contacting the lower surface of the lower electrode structure 244 of the capacitor 250 while connecting the first pad pattern 102 and the fourth pad pattern 202 to each other may be further formed.

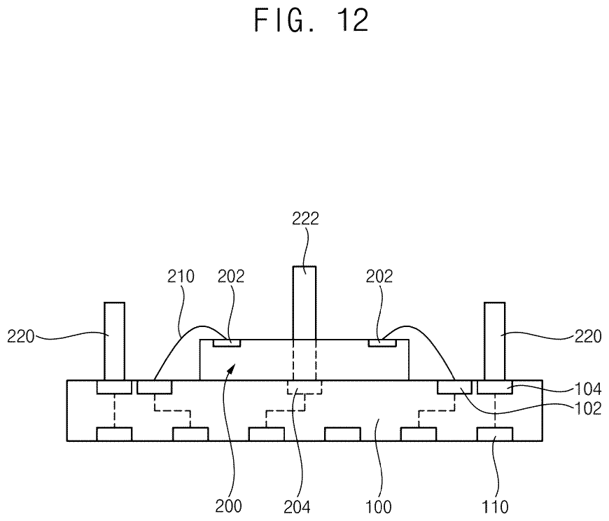

Referring to FIGS. 12 and 13, a first conductive post 220 may be formed on the second pad pattern 104 of the package substrate 100, and a second conductive post 222 may be formed on the third pad pattern 204 of the semiconductor chip 200.

In each cross-sectional view, because the second conductive post 222 is positioned adjacent the rear of the semiconductor chip 200, a portion of the second conductive post 222 is indicated by a dotted line.

A power voltage Vdd may be applied to one of the first conductive post 220 and the second conductive post 222, a ground voltage Vss may be applied to the other one of the first conductive post 220 and the second conductive post 222. Hereinafter, it will be described that the power voltage is applied to the first conductive post 220, and the ground voltage is applied to the second conductive post 222.

The first and second conductive posts 220 and 222 may be spaced apart from the semiconductor chip 200, and may be arranged closer to respective edges of the package substrate 100 than the semiconductor chip 200. In one or more example embodiments, the first and second conductive posts 220 and 222 may be closer to respective edges of the package substrate 100 than respective conductive wires 210.

An upper surface of the second conductive post 222 may be positioned higher than the upper surface of the first conductive post 220. That is, a vertical height of the second conductive post 222 from the first surface of the package substrate 100 may be greater than a vertical height of the first conductive post 220 from the first surface of the package substrate 100.

In one or more example embodiments, the first and second conductive posts 220 and 222 may extend vertically with respect to the first surface of the package substrate 100.

In one or more example embodiments, as illustrated in FIG. 4, at least one of the first and second conductive posts 220 and 222 may extend to have a non-vertical slope from the upper surface of the package substrate 100 or the upper surface of the semiconductor chip 200. At least one of the first and second conductive posts 220 and 222 may extend obliquely with respect to the upper surface of the package substrate 100 or the upper surface of the semiconductor chip 200, or may extend to have a curved shape or a bent shape at some portions thereof.

In one or more example embodiments, the first and second conductive posts 220 and 222 may be formed by performing a vertical wire bonding process.

In one or more example embodiments, the first and second conductive posts 220 and 222 may be formed by forming a mask pattern including an opening and then depositing a conductive material to fill the opening.

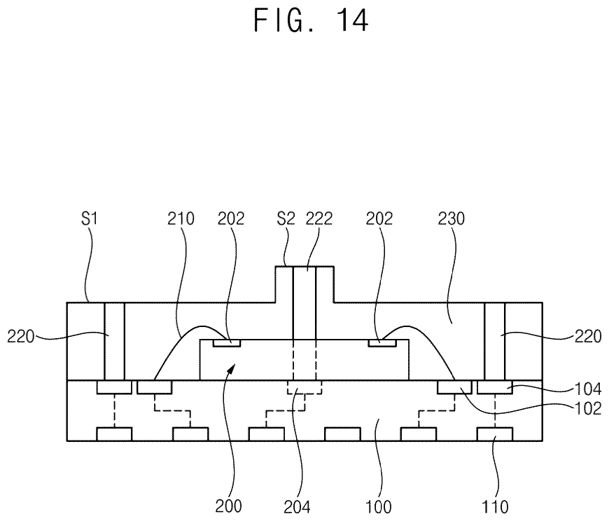

Referring to FIG. 14, a sealing member 230 may be formed on the package substrate 100 to cover the semiconductor chip 200 and one or more sidewalls of the first and second conductive posts 220 and 222.

For example, the sealing member 230 may include an epoxy mold compound (EMC). The sealing member 230 may include fillers serving as filling material and an epoxy resin serving as a binder for the fillers.

Particularly, the sealing member 230 may be formed on the package substrate 100 to cover the semiconductor chip 200 and the first and second conductive posts 220 and 222, and the upper portion of the sealing member 230 may be planarized until the upper surface of the second conductive post 222 may be exposed. The planarization process may include a grinding process.

Thereafter, the sealing member 230 may be removed except for a portion of the sealing member 230 surrounding the second conductive post 222 so that the upper surface of the first conductive post 220 may be exposed. The portion where the sealing member 230 is removed may be referred to as a recessed portion. Because the portion of the sealing member 230 surrounding the second conductive post 222 may not be removed, the portion of the sealing member 230 surrounding the second conductive post 222 may protrude upward from a first upper surface S1 of the recessed portion of the sealing member 230. Therefore, the portion of the sealing member 230 surrounding the second conductive post 222 is referred to as a protrusion 231.

The sealing member 230 may include the first upper surface S1 where the upper surface of the first conductive post 220 is exposed and a second upper surface S2 where the upper surface of the second conductive post 222 is exposed. Each of the first upper surface S1 and the second upper surface S2 may be substantially flat. The first upper surface S1 may correspond to a surface of the recessed portion, and the second upper surface S2 may correspond to an upper surface of the protrusion 231. The second upper surface S2 may be higher than the first upper surface S1.

When the planarization process is performed, a minimum thickness in the vertical direction of the sealing member 230 disposed on the upper surface of the semiconductor chip 200 may be in range of about 1 [symbol] to about 10 [symbol] . For example, the minimum thickness in the vertical direction of the sealing member 230 disposed on the upper surface of the semiconductor chip 200 may be about 5 [symbol] to about 6 [symbol] .

In one or more example embodiments, as illustrated in FIG. 2, the protrusion 231 may extend in one direction while surrounding the plurality of second conductive posts 222.

In one or more example embodiments, as illustrated in FIG. 3, the protrusions 231 may have a pillar shape surrounding each of the second conductive posts 222.

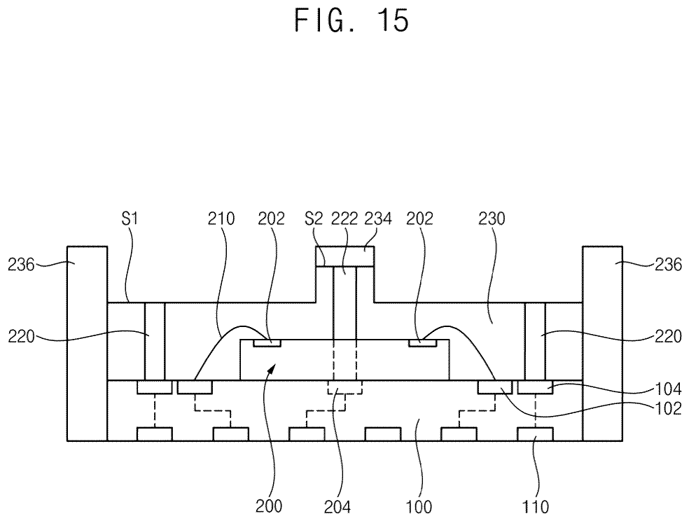

Referring to FIG. 15, a first mask pattern 234 may be formed to cover the second upper surface S2 of the sealing member 230 and the upper surface of the second conductive post 222. A second mask pattern 236 may be formed to cover the sidewalls of the package substrate 100 and the sealing member 230.

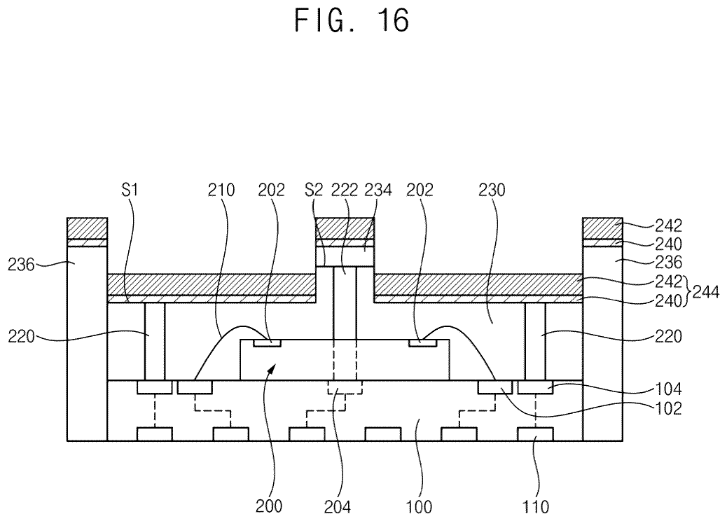

Referring to FIG. 16, a first metal layer 240 may be formed on the first upper surface S1 of the sealing member 230 and the first conductive post 220 to cover the first upper surface S1 of the sealing member 230 and the upper surface of the first conductive post 220. A second metal layer 242 may be formed on the first metal layer 240. The first and second metal layers 240 and 242 may serve as a lower electrode structure 244 of a capacitor 250.

Because the first metal layer 240 may be formed on the first upper surface S1 of the sealing member 230 and the first conductive post 220, the lower electrode structure 244 may not be formed along sidewalls of the protrusion 231 of the sealing member 230.

In the process of forming the lower electrode structure 244, the first and second metal layers 240 and 242 may be formed together on the first and second mask patterns 234 and 236.

The first metal layer 240 may be electrically connected to the first conductive post 220. The first metal layer 240 may be formed, e.g., by a sputtering process. The first metal layer 240 may serve as a seed metal layer for forming the second metal layer 242. In one or more example embodiments, the first metal layer 240 may include stainless steel SUS.

The second metal layer 242 may include copper. The second metal layer 242 may be formed, for example, by a sputtering process.

The upper surface of the second metal layer 242 formed on the first upper surface S1 of the sealing member 230 and the first conductive post 220 may be lower than the second upper surface of the sealing member 230.

Depending on a shape of the protrusion 231, the lower electrode structures 244 may be separated from each other by interposing the protrusion 231. Alternatively, the lower electrode structures 244 may be connected to each other at a location other than the protrusion 231.

In one or more example embodiments, as shown in FIG. 2, when the protrusion 231 has a shape extending in one direction, the lower electrode structures 244 may be separated from each other by interposing the protrusion 231.

In one or more example embodiments, as shown in FIG. 3, when the protrusions 231 has a plurality of pillar shapes spaced apart from each other, the lower electrode structure 244 may be connected to each other at a location other than the protrusion 231.

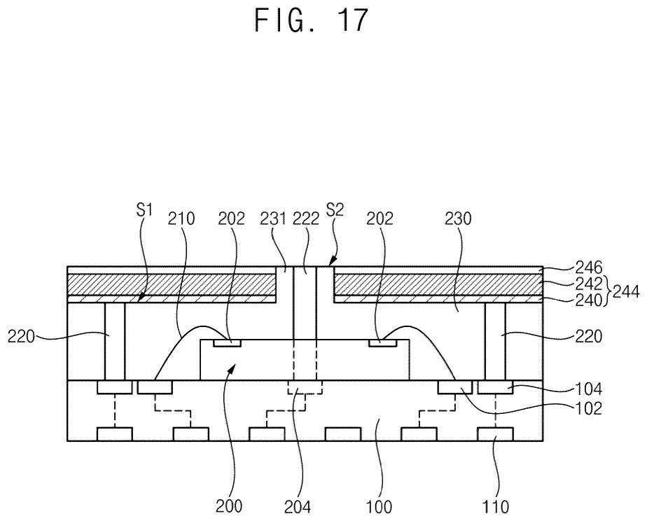

Referring to FIG. 17, a dielectric layer 246 may be formed on the second metal layer 242. The dielectric layer 246 may include, e.g., silicon oxide, silicon nitride, silicon oxynitride, titanium oxide, tantalum oxide, hafnium oxide, zirconium oxide, or polyimide (PI).

Thereafter, the first and second mask patterns 234 and 236 may be removed.

A planarization process may be performed until the upper surface of the dielectric layer 246, the second upper surface of the sealing member 230 and the upper surface of the second conductive post 222 may be planarized to each other. The planarization process may include, for example, a grinding process. In one or more example embodiments, the planarization process may not be performed.

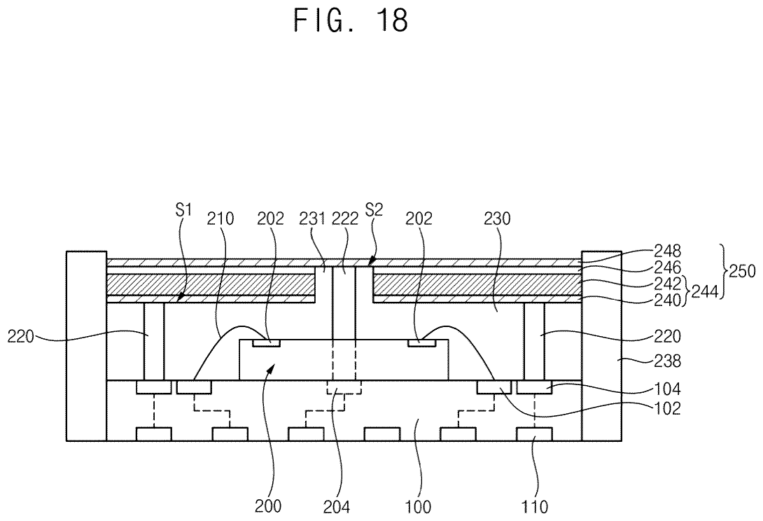

Referring to FIG. 18, a third mask pattern 238 may be formed to cover one or more sidewalls of the package substrate 100 and the sealing member 230.

An upper electrode 248 may be formed on the upper surface of the dielectric layer 246, the second upper surface of the sealing member 230, and the upper surface of the second conductive post 222. The upper electrode 258 may include a metal having higher oxidation resistance and having a strength higher than a strength of the second metal layer 242. The metal may include, for example, stainless steel.

The upper electrode 248 may be formed by, for example, a sputtering process. The upper electrode 248 may be electrically connected to the second conductive post 222.

Therefore, a capacitor 250 including the lower electrode structure 244, the dielectric layer 246, and the upper electrode 248 may be formed on the upper surfaces of the sealing member 230 and the first conductive post 220.

Thereafter, the third mask pattern 238 may be removed.

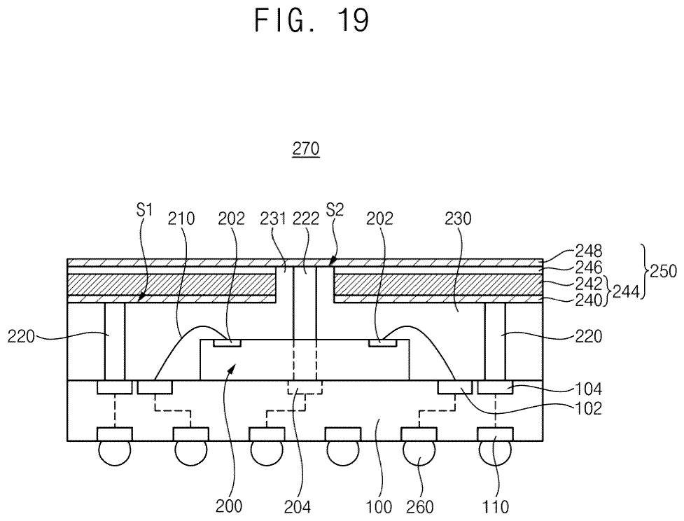

Referring to FIG. 19, external connection members 260 may be formed on the lower bonding pads 110 of the package substrate 100, respectively. Therefore, the semiconductor package 270 may be manufactured.

In one or more example embodiments, the process for forming the external connection members 260 may be performed after forming the sealing member 230. That is, first, the external connection members 260 may be formed, and then the processes described with reference to FIGS. 13 and 14 may be performed to form the capacitor 250.

As described above, a grounded electrode (e.g., the upper electrode) among the electrodes of the capacitor 250 may also serve as a shielding layer that shields electromagnetic waves generated from the semiconductor package 270 or introduced in the semiconductor package 270. Therefore, defects of the semiconductor package 270 due to the electromagnetic waves may be reduced.

In addition, because the semiconductor package 270 has a high-capacitance capacitor 250 disposed adjacent to the semiconductor chip 200, the signal integrity and the power integrity of the semiconductor package 270 may be improved, and the signal noise and the power noise may be reduced.

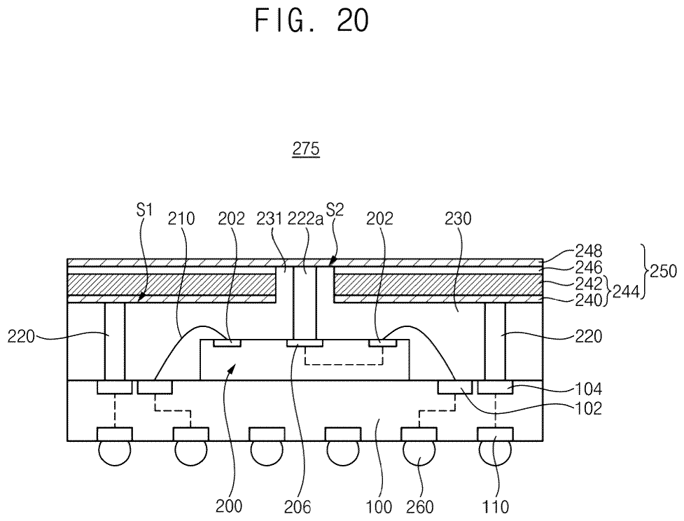

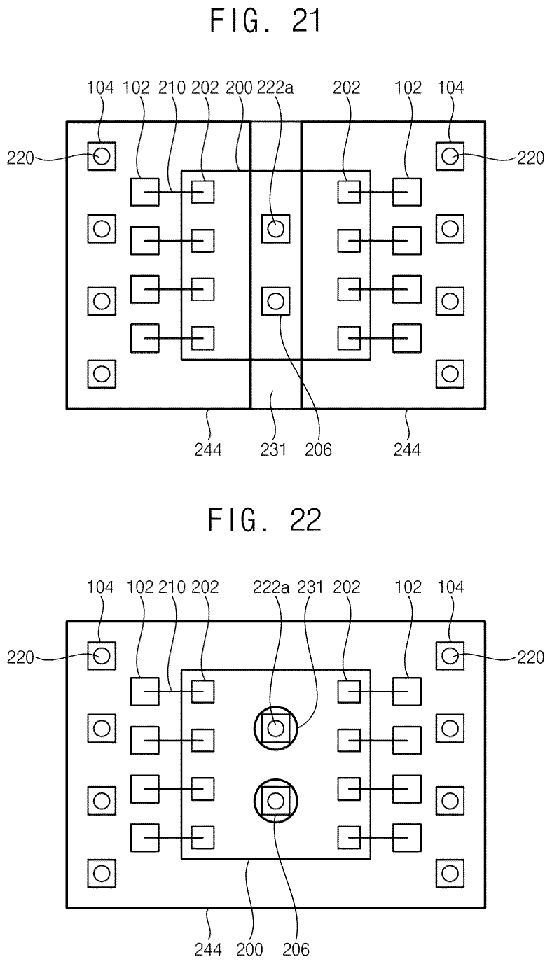

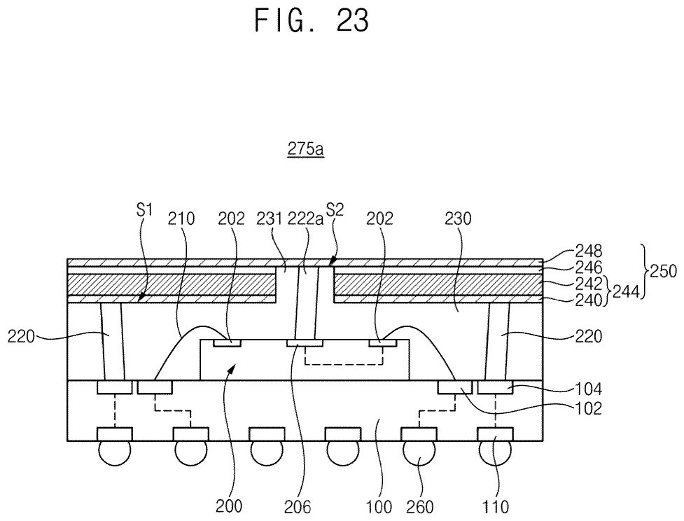

FIG. 20 is a cross-sectional view illustrating a semiconductor package according to one or more example embodiments. FIG. 21 is a plan view illustrating a semiconductor package according to one or more example embodiments. FIG. 22 is a plan view illustrating a semiconductor package according to one or more example embodiments. FIG. 23 is a cross-sectional view illustrating a semiconductor package according to one or more example embodiments.

The semiconductor package described with reference to FIG. 20 is similar or substantially identical to the semiconductor package illustrated in FIG. 1, except for a connection of the second conductive post 222. Therefore, redundant description may be omitted.

Referring to FIG. 20, a semiconductor package 275 may include the package substrate 100, the semiconductor chip 200, the conductive wire 210, the sealing member 230, the first conductive post 220, a second conductive post 222a, and the capacitor 250. The capacitor 250 may include the lower electrode structure 244, the dielectric layer 246, and the upper electrode 248.

Pad patterns 102 and 104 may be arranged on the first surface (e.g., an upper surface) of the package substrate 100. In one or more example embodiments, first pad patterns 102 for electrically connecting with the semiconductor chip 200 and second pad patterns 104 electrically connecting with the first conductive post 220 may be arranged on the first surface of the package substrate 100. Each of the first pad patterns 102 may be electrically connected to one among the internal wirings (e.g., the power wiring, the signal wiring, or the ground wiring) of the package substrate 100. Each of the second pad patterns 104 may be electrically connected to the power wiring or the ground wiring among the internal wirings of the package substrate 100.

The semiconductor chip 200 may be placed on the first surface of the package substrate 100.

Pad patterns 202 and 206 that are electrically connected to the circuit patterns and for inputting/outputting external signals may be placed on the upper surface of the semiconductor chip 200. In one or more example embodiments, fourth pad patterns 202 for connecting to the conductive wire 210 and fifth pad patterns 206 for connecting to the second conductive post 222a may be placed on the upper surface of the semiconductor chip 200. Each of the fourth pad patterns 202 may be electrically connected to the power wiring, the signal wiring, or the ground wiring of the package substrate 100. Each of the fifth pad patterns 206 may be electrically connected to one of the power wiring and the ground wiring of the package substrate 100 that is not connected to the second pad pattern 104.

An upper surface of the first conductive post 220 may contact the lower electrode structure 244. The first conductive post 220 may extend to the upper surface of the package substrate 100 through the sealing member 230, and may be electrically connected to the power wiring among the internal wirings of the package substrate 100. A lower surface of the first conductive post 220 may contact the second pad pattern 104 on the package substrate 100. The first conductive post 220 may pass through the sealing member 230 to connect one of the second pad patterns 104 and the lower electrode structure 244 of the capacitor 250.

The second conductive post 222a may be spaced apart from the lower electrode structure 244. An upper surface of the second conductive post 222a may contact the upper electrode 248. The second conductive post 222a may extend to the upper surface of the semiconductor chip 200 through the sealing member 230. In addition, the second conductive post 222a may be electrically connected to the first pad pattern 102. The first pad pattern 102 and the ground wiring among the internal wirings of the package substrate 100 may be electrically connected to each other by the conductive wire 210 formed by a wire bonding process. A lower surface of the second conductive post 222a may contact the fifth pad pattern 206 on the semiconductor chip 200. The second conductive post 222a may pass through the sealing member 230 to connect one of the fifth pad patterns 206 and the upper electrode 248 of the capacitor 250. In one or more example embodiments, the second conductive post 222a may pass through the lower electrode structure 244.

In one or more example embodiments, as illustrated in FIG. 21, the lower electrode structure 244 may have a shape that is separated into at least two pieces on the upper surface of the sealing member 230. For example, the protrusion 231 of the sealing member 230 may have a line shape extending in one direction.

In one or more example embodiments, as illustrated in FIG. 22, the lower electrode structures 244 may be connected to each other at a location other than the protrusion 231 to form one body. A plurality of protrusions 231 may be spaced apart from each other in one direction. For example, each of the protrusions 231 may have a pillar shape.

The external connection member 260 may be arranged on the lower bonding pad 110 of the second surface of the package substrate 100. The external connection member 260 may be electrically connected to each of pad patterns of the package substrate 100. In addition, the external connection member 260 may also be electrically connected to each of pad patterns of the semiconductor chip 200. Accordingly, signals may be input/output from outside of the semiconductor package 270 to the package substrate 100 and the semiconductor chip 200 via the external connection member 260.

In one or more example embodiments, the first conductive posts 220 may be arranged outside the conductive wire 210, and may be spaced apart from the conductive wire 210.

Each of the first conductive post 220 may be electrically connected to the second pad pattern 104 connected to the power wiring within the package substrate 100 and the lower electrode structure 244. Therefore, the power voltage may be applied to the lower electrode structure 244 through the external connection member 260, the internal wirings of the package substrate 100, the second pad pattern 104 and the first conductive post 220. That is, the first conductive post 220 may be electrically connected to one of the external connection members 260.

The second conductive post 222a may penetrate below the upper surface of the protrusion 231 of the sealing member 230. The second conductive post 222a may extend upward from the upper surface of one of the fifth pad patterns 206 to the lower surface of the upper electrode 248. The second conductive post 222a may contact the lower surface of the upper electrode 248. A plurality of second conductive posts 222a may be spaced apart from each other.

The second conductive post 222a may be insulated from the lower electrode structure 244, and may extend from the lower surface of the upper electrode 248 to the fifth pad pattern 206 of the semiconductor chip 200.

The second conductive post 222a may be electrically connected to the fourth pad pattern 202 electrically connected to the ground wiring of the package substrate 100 by the wiring of the circuit pattern of the semiconductor chip 200, among the fourth pad patterns 202. Accordingly, the upper electrode 248 may be grounded through the second conductive post 222a, the fifth pad pattern 206, the fourth pad pattern 202 connected to the ground wiring, the conductive wire 210, the first pad pattern 102, the internal wirings of the package substrate 100 and the external connecting member 260. That is, the second conductive post 222a may be electrically connected to one of the external connecting members 260.

In one or more example embodiments, as illustrated in FIG. 20, in the semiconductor package 275, the first and second conductive posts 220 and 222a may extend in the vertical direction perpendicular to the upper surface of the package substrate 100 or the upper surface of the semiconductor chip 200.

In one or more example embodiments, as shown in FIG. 23, in the semiconductor package 275a, at least one of the first and second conductive posts 220 and 222a may extend obliquely from the upper surface of the package substrate 100 or the upper surface of the semiconductor chip 200 with a non-vertical slope.

As described above, the second conductive post 222a may be formed on the fifth pad pattern 206 of the semiconductor chip 200. Therefore, the lower surface of the second conductive post 222a may be higher than the lower surface of the first conductive post 220. In addition, the upper surface of the second conductive post 222a may be higher than the upper surface of the first conductive post 220.

In one or more example embodiments, the first conductive post may contact the upper surface of the semiconductor chip, and the second conductive post may contact the upper surface of the package substrate.

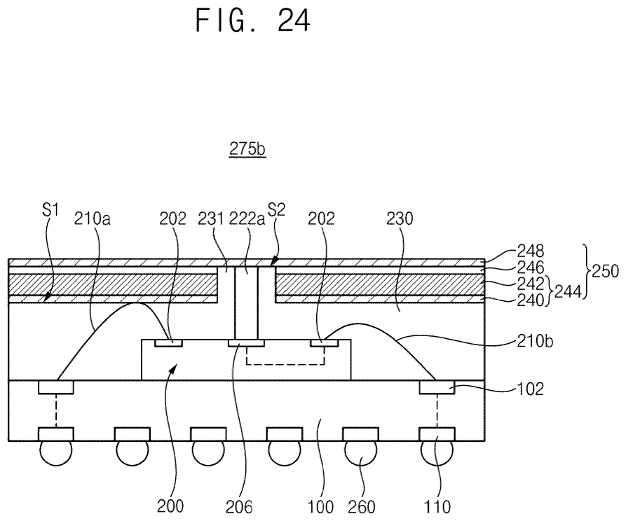

FIG. 24 is a cross-sectional view showing a semiconductor package according to one or more example embodiments.

The semiconductor package 275b described with reference to FIG. 24 is similar to or substantially identical to the semiconductor package illustrated in FIG. 8, except for the connection of the second conductive post. Therefore, redundant description may be omitted.

Referring to FIG. 24, pad patterns 102 and 104 may be arranged on the first surface (e.g., the upper surface) of the package substrate 100. In one or more example embodiments, first pad patterns 102 for electrically connecting with the semiconductor chip 200 and second pad patterns 104 for electrically connecting with the first conductive post 220 may be arranged on the first surface of the package substrate 100. The first and second pad patterns 102 and 104 may be substantially identical to those described with reference to FIGS. 20 and 21.

Pad patterns 202 and 206 for electrically connecting with the circuit patterns and inputting/outputting external signals may be arranged on the upper surface of the semiconductor chip 200. In one or more example embodiments, fourth pad patterns 202 for connecting with the conductive wire 210 and fifth pad patterns 206 for connecting with the second conductive post 222a may be arranged on the upper surface of the semiconductor chip 200. The fourth and fifth pad patterns 202 and 206 may be substantially identical to those described with reference to FIGS. 20 and 21.

A first conductive wire 210a may contact a lower surface of the lower electrode structure 244 of the capacitor 250 while connecting the first pad pattern 102 and the fourth pad pattern 202 to each other. The power voltage may be applied to the lower electrode structure 244 through the first conductive wire 210a.

A second conductive wire 210b may be further included that connects the first pad pattern 102 and the fourth pad pattern 202 to each other, and the second conductive wire 210b may not contact the lower surface of the lower electrode structure 244 of the capacitor 250. The second conductive wire 210b may be substantially identical to the conductive wire described with reference to FIG. 1.

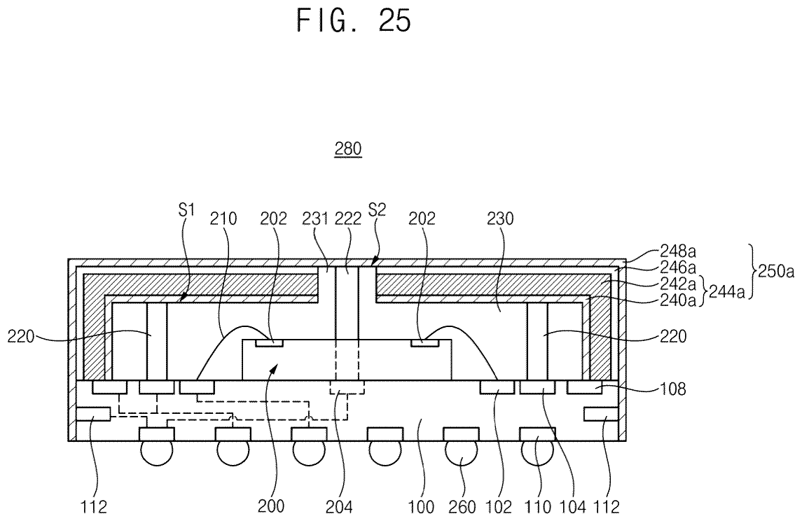

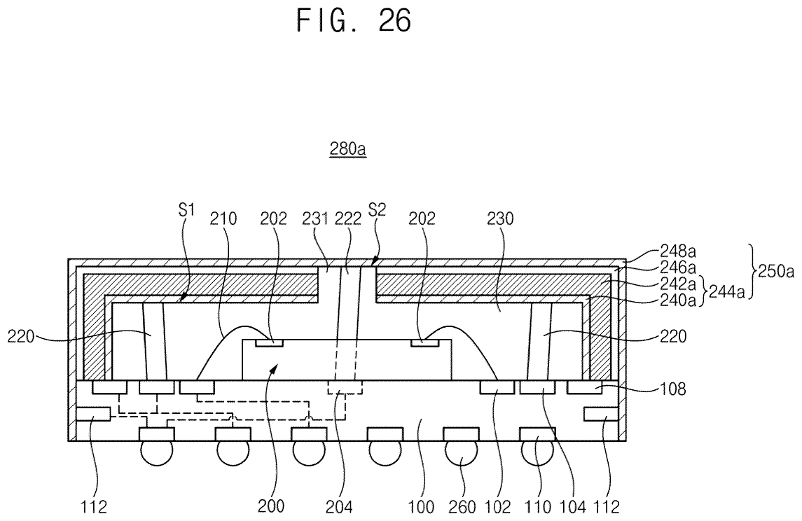

FIG. 25 is a cross-sectional view illustrating a semiconductor package according to one or more example embodiments. FIG. 26 is a cross-sectional view illustrating a semiconductor package according to one or more example embodiments.

The semiconductor package 280 illustrated in FIG. 25 may be similar to or substantially identical to the semiconductor package illustrated in FIG. 1, except for shapes of a package substrate, a sealing member, and a capacitor.

Referring to FIG. 25, the semiconductor package 280 may include the package substrate 100, the semiconductor chip 200, the conductive wire 210, the sealing member 230, the first conductive post 220, the second conductive post 222 and a capacitor 250a. The capacitor 250a may include a lower electrode structure 244a, a dielectric layer 246a, and an upper electrode 248a.

First pad patterns 102 for electrically connecting with the semiconductor chip 200, second pad patterns 104 for electrically connecting with the first conductive post 220, third pad patterns 204 for electrically connecting with the second conductive post 222, and a sixth pad pattern 108 for directly contacting the lower electrode structure 244a may be arranged on the first surface of the package substrate 100. A conductive pattern 112 may be disposed inside the package substrate 100. The conductive pattern 112 may be exposed by sidewalls of the package substrate 100, and may directly contact the upper electrode 248a of the capacitor 250a.

The second pad pattern 104 and the sixth pad pattern 108 may be spaced apart from the first pad pattern 102, and the second pad pattern 104 and the sixth pad pattern 108 may be arranged closer to an edge of the package substrate 100 than the first pad pattern 102.

Each of the first pad patterns 102 may be electrically connected to the power wiring, the signal wiring, or the ground wiring.

The second and sixth pad patterns 104 and 108 may be electrically connected to one of the power wiring and the ground wiring. The power voltage or the ground voltage may be applied to the second and sixth pad patterns 104 and 108. For example, the power voltage may be applied to the second and sixth pad patterns 104 and 108.

The conductive pattern 112 may be connected to the ground wiring arranged inside the package substrate 100 and for being applied a ground voltage. In addition, the conductive pattern 112 may be electrically connected to the external connection member 260.

The sealing member 230 may cover the semiconductor chip 200 and the conductive wires 210 on the package substrate 100. The sealing member 230 may not be formed on the edge portion of the package substrate 100. The sealing member 230 may cover an entirety of the package substrate 100 except for the edge portion of the package substrate 100. At least a portion of the upper surface of the sixth pad pattern 108 may be exposed outside sidewalls of the sealing member 230.

In one or more example embodiments, similar to that described in FIG. 1, the sealing member 230 may include the protrusion.

The capacitor 250a may be disposed on the upper surface and the sidewalls of the sealing member 230.

In one or more example embodiments, a stacked structure of the lower electrode structure 244a and the dielectric layer 246a may be arranged on the first upper surface and four sidewalls of the sealing member 230. The stacked structure of the lower electrode structure 244a and the dielectric layer 246a may be spaced apart from each other with the protrusion 231 of the sealing member 230 interposed therebetween. The stacked structure of the lower electrode structure 244a and the dielectric layer 246a may cover the entire upper surface and sidewalls of the sealing member 230 except for the protrusion 131 of the sealing member 230. The upper electrode 248a may cover the upper surface of the dielectric layer 246a, the protrusion 131 of the sealing member 230 and the sidewalls of the package substrate 100.

Therefore, the upper surface and outer sidewalls of the semiconductor package 280 may be covered with only the upper electrode 248a. Only the upper electrode 248a may be exposed on the upper surface and the outer sidewalls of the semiconductor package 280.

An end of the lower electrode structure 244a formed on the sidewalls of the sealing member 230 may contact the sixth pad pattern 108. Therefore, the power voltage may be applied to the lower electrode structure 244a through the sixth pad pattern 108.

The upper electrode 248a may contact the conductive pattern 112 exposed by the sidewall of the package substrate 100. Therefore, the upper electrode 248a may be grounded through the conductive pattern 112, the internal wirings of the package substrate 100 and the external connection member 260.

In one or more example embodiments, the conductive wire 210 may be substantially identical to that described with reference to FIG. 1.

In one or more example embodiments, the first conductive post 220 may be substantially identical to that described with reference to FIG. 1. The first conductive post 220 may contact the lower electrode structure 244a of the capacitor 250a and the second pad pattern 104. Therefore, the power voltage may be applied to the lower electrode structure 244a through the first conductive post 220 and the sixth pad pattern 108.

In one or more example embodiments, the second conductive post 222 may be substantially identical to that described with reference to FIG. 1. The second conductive post 222 may contact the upper electrode 248a of the capacitor 250a and the third pad pattern 204. Therefore, the upper electrode 248a may be grounded through the second conductive post 222 and the conductive pattern 112.

In one or more example embodiments, the second conductive post may be substantially identical to that described with reference to FIG. 20. That is, the second conductive post may contact the fifth pad pattern 206 of the semiconductor chip 200.

In one or more example embodiments, as shown in FIG. 25, the first and second conductive posts 220 and 222 may extend in the vertical direction perpendicular to the first surface of the package substrate 100.

In one or more example embodiments, as shown in FIG. 26, in the semiconductor package 280a, at least one of the first and second conductive posts 220 and 222 may extend obliquely from a flat surface parallel to the first surface of the package substrate 100 to have a non-perpendicular slope. At least one of the first and second conductive posts 220 and 222 may be extended obliquely with respect to the first surface of the package substrate 100.

In the capacitor 250a included in the semiconductor package 280, the lower electrode structure 244a and the upper electrode 248a may be also formed on the upper surface and the sidewalls of the sealing member 230. Therefore, an area where the lower electrode structure 244a and the upper electrode 248a face each other increases, so that the capacitor may have high capacitance. Therefore, the semiconductor package 280 may have excellent characteristics.

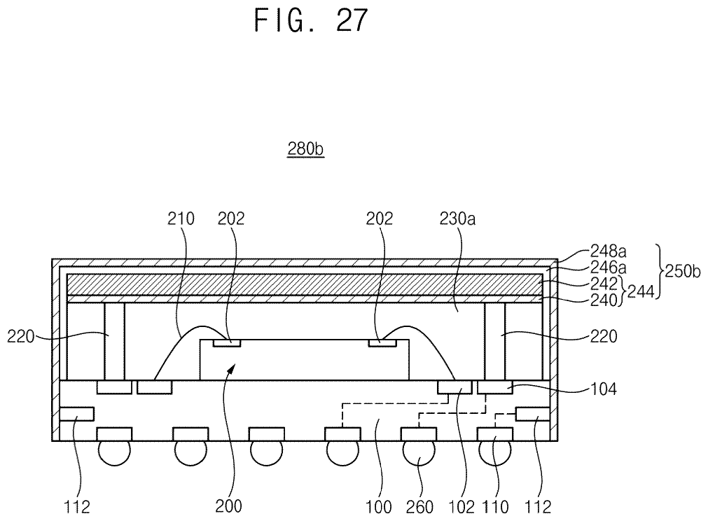

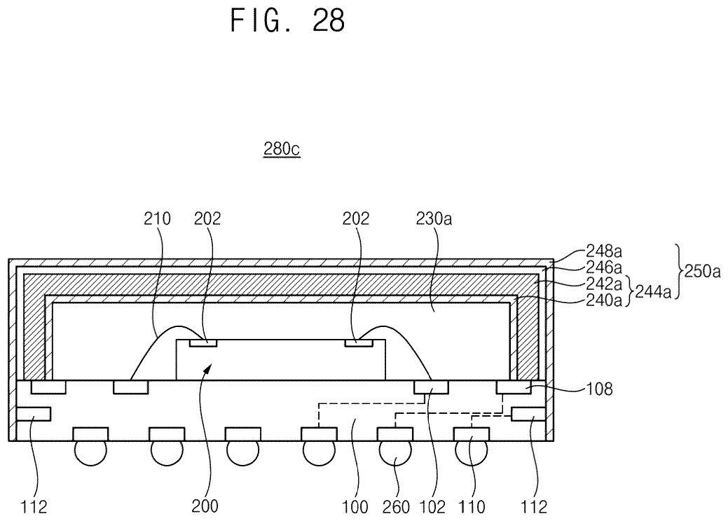

FIG. 27 is a cross-sectional view showing a semiconductor package according to one or more example embodiments.

The semiconductor package 280b illustrated in FIG. 27 is substantially identical to the semiconductor package illustrated in FIG. 25, except for shapes of a capacitor 250b and a sealing member 230a and ones of pad patterns.

Referring to FIG. 27, the first surface of the package substrate 100 may include first pad patterns 102 for electrically connecting with the semiconductor chip 200 and second pad patterns 104 for electrically connecting with the first conductive post 220. However, a third pad pattern directly contacting the lower electrode structure 244 of the capacitor 250b may not be included in the first surface of the package substrate 100. A conductive pattern 112 directly contacting the upper electrode 248a may be arranged on one or more sidewalls of the package substrate 100.

Each of the first pad patterns 102 may be electrically connected to the power wiring, the signal wiring, or the ground wiring. The second pad patterns 104 may be electrically connected to, e.g., the power wiring. The conductive pattern 112 may be connected to, for example, the ground wiring to which the ground voltage is applied.

The sealing member 230a may cover the semiconductor chip 200 and the conductive wires 210 on the package substrate 100. The sealing member 230a may cover an entirety of remaining portions of the package substrate 100 except for an edge portion of the package substrate 100. The sealing member 230a may cover an entirety of the upper surfaces of the first and second pad patterns 102 and 104. The upper surface of the sealing member 230a may have a flat surface, and may not include a protrusion.

In one or more example embodiments, the lower electrode structure 244 may cover the entire upper surface of the sealing member 230a. The lower electrode structure 244 may not be formed on the sidewalls of the sealing member 230a. The dielectric layer 246a may be disposed on the surface of the lower electrode structure 244 and four sidewalls of the sealing member 230a. However, the dielectric layer 246a may not be formed on the sidewalls of the package substrate 100.

The upper electrode 248a may cover the surface of the dielectric layer 246a and the sidewalls of the package substrate 100. Therefore, an uppermost surface and an outer wall of the semiconductor package 280b may be covered with only the upper electrode 248a. Only the upper electrode 248a may be exposed on the uppermost surface and the outer wall of the semiconductor package 280b.

The upper electrode 248a formed on the sidewalls of the sealing member 230a may contact the conductive pattern 112 exposed by one or more sidewalls of the package substrate 100. Therefore, the upper electrode 248a may be grounded through the conductive pattern 112, the internal wirings of the package substrate 100 and the external connection member 260.

In one or more example embodiments, the first conductive post 220 may be substantially identical to that described with reference to FIG. 1. The first conductive post 220 may contact the lower electrode structure 244 and the second pad pattern 104. The first conductive post 220 may be connected to the lower electrode structure 244. The power voltage may be applied to the lower electrode structure 244a by the first conductive post 220.

In this case, the second conductive post 222 contacting the third pad pattern 204 and being grounded may not be arranged.

The semiconductor package 280b may not include the protrusion in the sealing member 230a. Accordingly, the semiconductor package 280b may be manufactured by simple processes.

FIG. 28 is a cross-sectional view showing a semiconductor package according to one or more example embodiments. The semiconductor package illustrated in FIG. 28 may be substantially identical to the semiconductor package described with reference to FIG. 18, except that the first and second conductive posts 220 and 222 are not included and configurations of a sealing member and pad patterns are different.

Referring to FIG. 28, in the semiconductor package 280c, first pad patterns 102 for electrically connecting with the semiconductor chip 200 and sixth pad patterns 108 directly contacting the lower electrode structure 244a may be arranged on the first surface of the package substrate 100. The conductive pattern 112 may be arranged inside the package substrate 100. The conductive pattern 112 may be exposed by the sidewalls of the package substrate 100, and may contact the upper electrode 248a. The semiconductor package 280c may not include the second pad pattern and the third pad pattern illustrated in FIG. 25.

Each of the first pad patterns 102 may be electrically connected to the power wiring, the signal wiring, or the ground wiring.

The sixth pad patterns 108 may be electrically connected to the power wiring. The sixth pad patterns 108 may be applied with the power supply voltage.

The conductive pattern 112 may be connected to the ground wiring to which the ground voltage is applied.

The sealing member 230a may cover the semiconductor chip 200 and the conductive wires 210 on the package substrate 100. The sealing member 230a may cover an entirety of the remaining portions of the package substrate 100 except for the edge portion of the package substrate 100. The sealing member 230a may be formed so that at least a portion of the upper surface of the sixth pad pattern 108 may be exposed. The sealing member 230a may have a flat upper surface, and may not include the protrusion 231.

The capacitor 250a may be arranged on an upper surface and sidewalls of the sealing member 230a. In one or more example embodiments, a stacked structure of the lower electrode structure 244a and the dielectric layer 246a may be arranged on the flat surface of the upper surface of and the four sidewalls of the sealing member 230a. The stacked structure of the lower electrode structure 244a and the dielectric layer 246a may cover the entire upper surface and sidewalls of the sealing member 230a. The stacked structure of the lower electrode structure 244a and the dielectric layer 246a may not cover the sidewalls of the package substrate 100.

The upper electrode 248a may cover the surface of the dielectric layer 246a and the sidewalls of the package substrate 100. Therefore, an uppermost surface and an outer wall of the semiconductor package 280c may be covered with only the upper electrode 248a. Only the upper electrode 248a may be exposed on the uppermost surface and the outer wall of the semiconductor package 280c.

An end of the lower electrode structure 244a formed on the sidewalls of the sealing member 230a may contact the sixth pad pattern 108. Therefore, the power voltage may be applied to the lower electrode structure 244a through the sixth pad pattern 108.

The upper electrode 248a may contact the conductive pattern 112 exposed on the sidewalls of the package substrate 100. Therefore, the upper electrode 248a may be grounded through the conductive pattern 112, the internal wirings of the package substrate 100 and the external connection member 260.

The semiconductor package 280c may not include the first conductive post and the second conductive post of the semiconductor package shown in FIG. 25. Therefore, the semiconductor package 280c may be manufactured by simple processes.

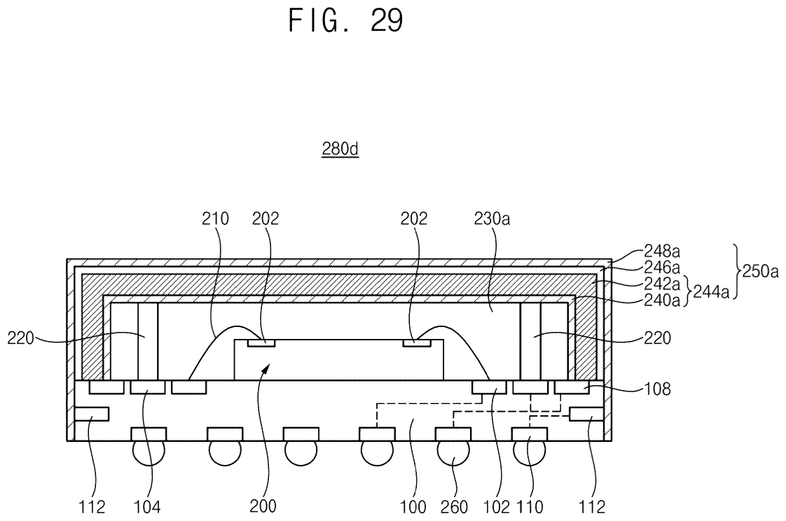

FIG. 29 is a cross-sectional view illustrating a semiconductor package according to one or more example embodiments.

Referring to FIG. 29, in the semiconductor package 280d, first pad patterns 102 for electrically connecting with the semiconductor chip 200, second pad patterns 104 for electrically connecting with the first conductive post 220 and sixth pad patterns 108 for directly contacting the lower electrode structure 244a may be arranged on the upper surface of the package substrate 100. The conductive pattern 112 for directly contacting the upper electrode 248a may be arranged on the sidewalls of the package substrate 100.

Each of the first pad patterns 102 may be electrically connected to the power wiring, the signal wiring, or the ground wiring. The second pad patterns 104 may be electrically connected to the power wiring. The sixth pad patterns 108 may be connected to the power wiring. The conductive pattern 112 may be connected to the ground wiring to which the ground voltage is applied.

The sealing member 230a may be disposed on the package substrate 100 to cover the semiconductor chip 200 and the conductive wires 210. The sealing member 230a may cover an entirety of remaining portions of the package substrate 100 except for an edge portion of the package substrate 100. The sealing member 230a may cover the entirety of the upper surfaces of the first and second pad patterns 102 and 104 and expose at least a portion of the sixth pad patterns 108. The upper surface of the sealing member 230a may have a flat surface and may not include the protrusion 231.

The capacitor 250a may be arranged on the upper surface and sidewalls of the sealing member 230a.

In one or more example embodiments, a stacked structure of the lower electrode structure 244a and the dielectric layer 246a may be arranged on the flat surface of the upper surface of the sealing member 230a and on the four sidewalls. The stacked structure of the lower electrode structure 244a and the dielectric layer 246a may cover the entirety of an upper surface and sidewalls of the sealing member 230a.

The upper electrode 248a may cover the surface of the dielectric layer 246a and the sidewalls of the package substrate 100. Therefore, the upper surface and the outer sidewalls of the semiconductor package 280d may be covered with only the upper electrode 248a. Only the upper electrode 248a may be exposed on the upper surface and the outer sidewalls of the semiconductor package 280d. An end of the lower electrode structure 244a formed on the sidewall of the sealing member 230a may contact the sixth pad pattern 108. Therefore, the power voltage may be applied to the lower electrode structure 244a through the sixth pad pattern 108.

The upper electrode 248a may contact the conductive pattern 112 exposed on the sidewall of the package substrate 100. Therefore, the upper electrode 248a may be grounded through the conductive pattern 112, the internal wirings of the package substrate 100 and the external connection member 260.

In one or more example embodiments, the first conductive post 220 may be substantially identical to that described with reference to FIG. 25. The first conductive post 220 may contact the lower electrode structure 244a and the second pad pattern 104.

In this case, the second conductive post 222 contacting the third pad pattern 204 and being grounded may not be arranged.

In the semiconductor package 280d, the sealing member 230a may not include the protrusion. Accordingly, the semiconductor package 280d may be manufactured through simple processes.

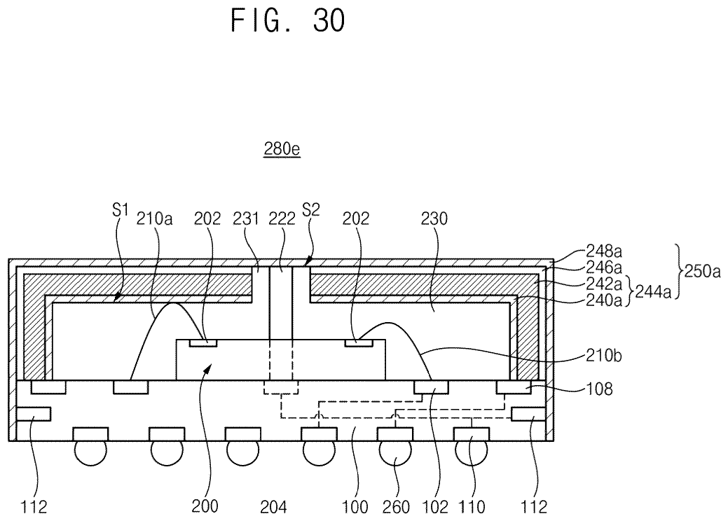

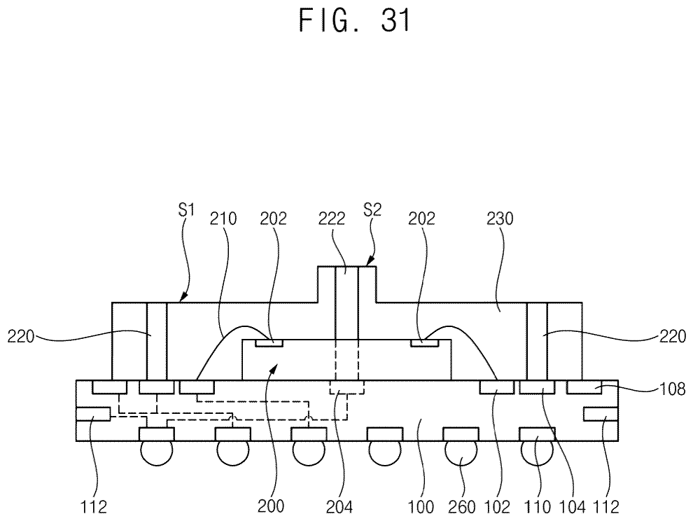

FIG. 30 is a cross-sectional view illustrating a semiconductor package according to one or more example embodiments.

The semiconductor package 280e shown in FIG. 30 may be substantially identical to the semiconductor package shown in FIG. 25 except that the first conductive post 220 is not included and a shape of a conductive wire is different.

Referring to FIG. 30, in the semiconductor package 280e, first pad patterns 102 for electrically connecting with the semiconductor chip 200, third pad patterns 204 for electrically connecting with the second conductive post 222, and sixth pad patterns 108 for directly contacting the lower electrode structure 244a may be arranged on the first surface of the package substrate 100.

In one or more example embodiments, the second pad patterns electrically connected with the first conductive post may not be arranged on the first surface of the package substrate 100. In addition, the first conductive post 220 may not be included on the first surface of the package substrate 100.

In one or more example embodiments, the second pad patterns electrically connecting with the first conductive posts may be arranged on the first surface of the package substrate 100, and thus the first conductive posts 220 may be arranged on the first surface of the package substrate 100.

The conductive pattern 112 may be arranged inside the package substrate 100. The conductive pattern 112 may be exposed by the sidewall of the package substrate 100, and may directly contact the upper electrode 248a.

A first conductive wire 210a may contact a lower surface of the lower electrode structure 244a while connecting the first pad pattern 102 and the fourth pad pattern 202 to each other. The power voltage may be applied to the lower electrode structure 244a through the first conductive wire 210a.

One or more example embodiments may include a second conductive wire 210b that connects the first pad pattern 102 and the fourth pad pattern 202 to each other, and does not contact the lower surface of the lower electrode structure 244a of the capacitor 250a. The second conductive wire 210b may be substantially identical to the conductive wire described with reference to FIG. 1.

The capacitor 250a may be arranged on the upper surface and one or more sidewalls of the sealing member 230. The capacitor 250a may be substantially identical to that described with reference to FIG. 25.

The second conductive post 222 may be substantially identical to that described with reference to FIG. 25. The second conductive post 222 may contact the upper electrode 248a and the third pad pattern 204.

The upper electrode 248a may contact the conductive pattern 112 exposed by the sidewall of the package substrate 100. Therefore, the upper electrode 248a may be grounded through the conductive pattern 112 and the second conductive post 222.

The power voltage may be supplied to the lower electrode structure 244a through the first conductive wire 210a and the sixth pad pattern 108.

In one or more example embodiments, the second conductive post 222 may not be formed.

FIGS. 31 to 33 are cross-sectional views illustrating a method of manufacturing a semiconductor package according to one or more example embodiments.

With reference to FIGS. 31 to 33, a method of manufacturing the semiconductor package shown in FIG. 25 will be mainly described.

Referring to FIG. 31, the semiconductor chip 200 may be placed on the first surface of the package substrate 100.

In one or more example embodiments, the upper surface of the package substrate 100 may include the first pad patterns 102 for electrically connecting with the semiconductor chip 200, the second pad patterns 104 for electrically connecting with the first conductive post 220, and the third pad patterns 204 for electrically connecting with the second conductive post 222. In addition, the sixth pad patterns 108 for directly contacting the lower electrode structure of the capacitor may be included on the package substrate 100.

In one or more example embodiments, the second pad patterns and/or the sixth pad patterns may not be included on the package substrate 100.

A wire bonding process may be performed to form the conductive wire 210 first electrically connecting the fourth pad patterns 202 of the semiconductor chip 200 and the First pad patterns 102 of the package substrate 100.

Thereafter, the first conductive post 220 may be formed on the second pad pattern 104 of the package substrate 100, and the second conductive post 222 may be formed on the third pad pattern 204 of the package substrate 100.

In one or more example embodiments, the first and second conductive posts 220 and 222 may extend in the vertical direction perpendicular to the first surface of the package substrate 100.

In one or more example embodiments, as shown in FIG. 26, at least one of the first and second conductive posts 220 and 222 may extend from the upper surface of the package substrate 100 to have an angle other than vertical. At least one of the first and second conductive posts 220 and 222 may extend obliquely with respect to the upper surface of the upper surface of the package substrate 100.

In one or more example embodiments, the first and second conductive posts 220 and 222 may be formed by performing a vertical wire bonding process. In one or more example embodiments, the first and second conductive posts 220 and 222 may also be formed by forming a mask pattern including an opening and then filling the opening with a conductive material.

The sealing member 230 may be formed on the package substrate 100 to cover the semiconductor chip 200 and at least a portion of the sidewalls of the first and second conductive posts 220 and 222.

Particularly, the sealing member 230 may be formed on the package substrate 100 to cover the semiconductor chip 200 and the first and second conductive posts 220 and 222, and an upper portion of the sealing member 230 may be planarized until the upper surface of the second conductive post 222 may be exposed. The planarization process may include a grinding process.

Thereafter, remaining portions of the sealing member 230 except for a portion of the sealing member 230 surrounding the second conductive post 222 may be removed to expose the upper surface of the first conductive post 220. In addition, the sealing member 230 on an edge portion of the package substrate 100 may be removed. Therefore, at least a portion of the sixth pad pattern 108 may be exposed on outside of the sealing member 230.

The sealing member 230 may include a first upper surface S1 where the upper surface of the first conductive post 220 is exposed and a second upper surface S2 where the upper surface of the second conductive post 222 is exposed.

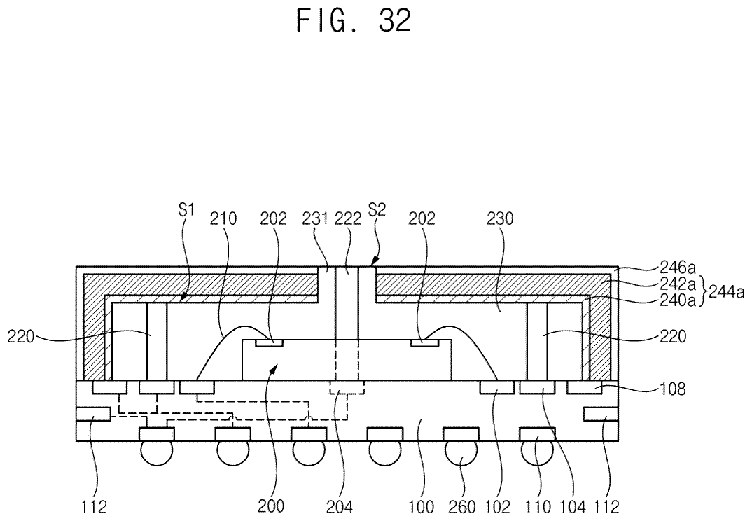

Referring to FIG. 32, a first mask pattern may be formed to cover the second upper surface S2 of the sealing member 230 and the upper surface of the second conductive post 222. In addition, a second mask pattern may be formed to cover the sidewalls of the package substrate 100.

A first metal layer 240a covering the first upper surface S1 and sidewall of the sealing member 230 and the upper surface of the first conductive post 220 may be formed on the first upper surface S1 and sidewall of the sealing member 230 and the upper surface of the first conductive post 220. A second metal layer 242a may be formed on the first metal layer 240a. The first and second metal layers 240a and 242a may serve as the lower electrode structure 244a of the capacitor 250a.

An end of the lower electrode structure 244a may extend to an upper surface of the sixth pad pattern 208 of the package substrate 100. Therefore, the end of the lower electrode structure 244a may contact the sixth pad pattern 208. The dielectric layer 246a may be formed on the second metal layer 242a.

Thereafter, the first and second mask patterns may be removed.

A planarization process may be performed so that the upper surface of the dielectric layer 246a, the second upper surface of the sealing member 230, and the upper surface of the second conductive post 222 may be coplanar with each other. The planarization process may include a grinding process. In one or more example embodiments, the planarization process may not be performed.

The lower electrode structure 244a and the dielectric layer 246a may not be formed on the sidewalls of the package substrate 100. After forming the dielectric layer 246a, the sidewalls of the package substrate 100 may be exposed.

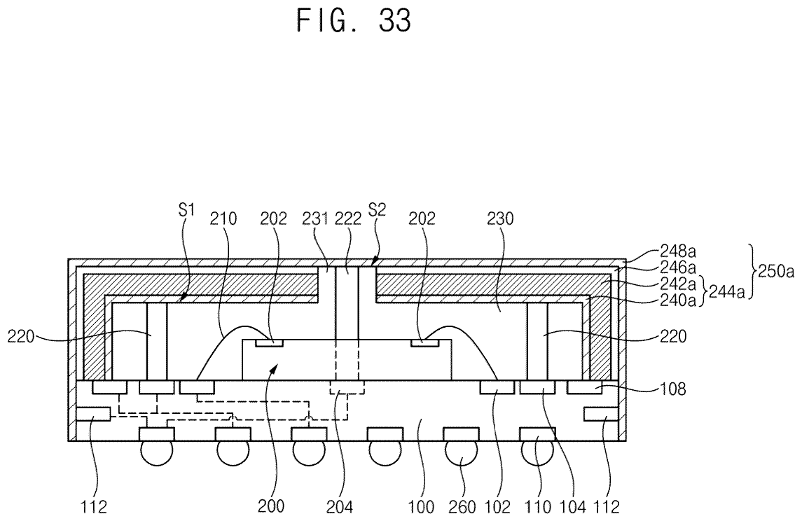

Referring to FIG. 33, the upper electrode 248a may be formed on the upper surface of the dielectric layer 246a, the second upper surface of the sealing member 230, the upper surface of the second conductive post 222 and the sidewall of the package substrate 100.

Therefore, the capacitor 250a including the lower electrode structure 244a, the dielectric layer 246a, and the upper electrode 248a may be formed on the upper surfaces of the sealing member 230 and the first conductive post 220.

Thereafter, the external connection member 260 may be formed on each of the lower bonding pads 110 of the package substrate 100.

By performing the above process, the semiconductor package can be manufactured.

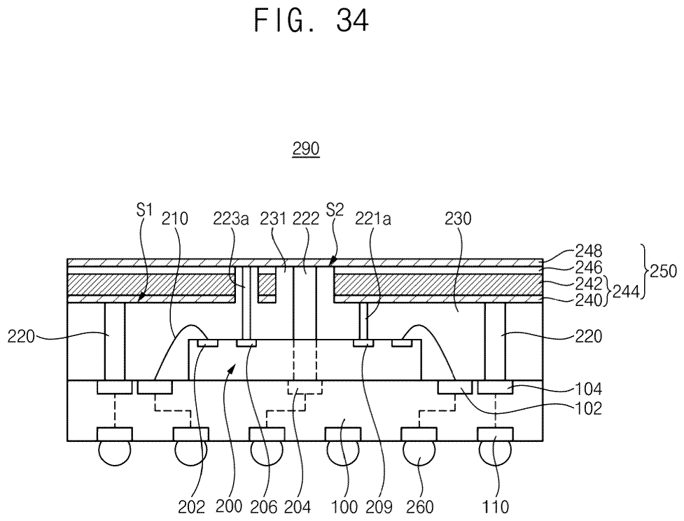

FIG. 34 is a cross-sectional view illustrating a semiconductor package according to one or more example embodiments. The semiconductor package 290 shown in FIG. 34 is substantially identical to the semiconductor package shown in FIG. 1, except for third and fourth conductive posts and a shape of a capacitor.

Referring to FIG. 34, first pad patterns 102 for electrically connecting with the semiconductor chip 200, second pad patterns 104 for electrically connecting with the first conductive post 220, and third pad patterns 204 for electrically connecting with the second conductive post 222 may be arranged on the first surface of the package substrate 100.

An upper surface of the first conductive post 220 may contact the lower electrode structure 244 of the capacitor 250, and a lower surface of the first conductive post 220 may contact the second pad pattern 104. An upper surface of the second conductive post 222 may contact the upper electrode 248 of the capacitor 250, and a lower surface of the second conductive post 222 may contact the third pad pattern 204. The fourth pad pattern 202, the fifth pad pattern 206, and the sixth pad pattern 209 may be arranged on the upper surface of the semiconductor chip 200. In one or more example embodiments, the fourth pad patterns 202 may be electrically connected to the conductive wire 210.

A third conductive post 221a may contact the sixth pad pattern 209. A fourth conductive post 223a may contact the fifth pad pattern 206.

In one or more example embodiments, the first and third conductive posts 220 and 221a may be electrically connected to the power wiring of the package substrate 100. For example, the third conductive post 221a may be electrically connected to the power wiring of the package substrate 100 via the conductive wire 210.

In one or more example embodiments, the second and fourth conductive posts 222 and 223a may be electrically connected to the ground wiring of the package substrate 100. For example, the fourth conductive post 223a may be electrically connected to the ground wiring of the package substrate 100 via the conductive wire 210.

In FIG. 34, widths of the third and fourth conductive posts 221a, 223a are shown to be smaller than the widths of the first and second conductive posts 220 and 222, but are not limited thereto. The widths of the third and fourth conductive posts 221a, 223a may be substantially identical to or different from the widths of the first and second conductive posts 220 and 222.

In one or more example embodiments, at least one of the third and fourth conductive posts contacting the upper surface of the semiconductor chip may be further included.

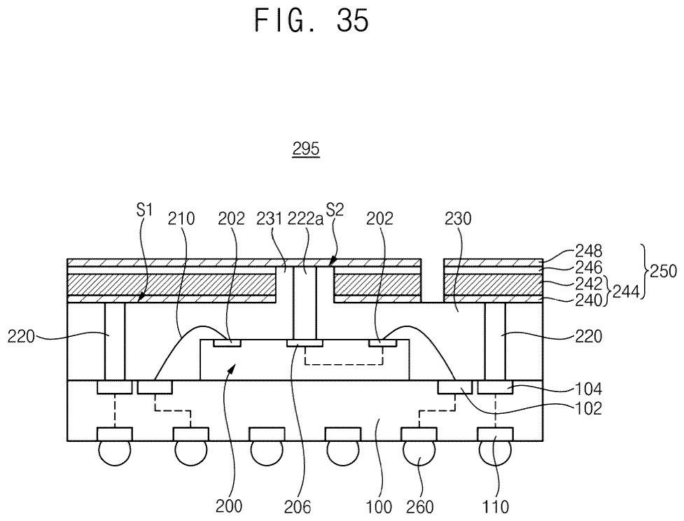

FIG. 35 is a cross-sectional view illustrating a semiconductor package according to one or more example embodiments.

The semiconductor package 295 shown in FIG. 35 is substantially identical to the semiconductor package illustrated in FIG. 20, except for a capacitor.

Referring to FIG. 35, the capacitor 250 may not completely cover the sealing member 230 on the semiconductor package 295. Therefore, a portion of the sealing member 230 may be exposed on the upper surface of the semiconductor package 295.

In one or more example embodiments, the capacitor 244 may not completely cover the sealing member 230 on the upper side of the semiconductor package in the same manner as in FIG. 35.

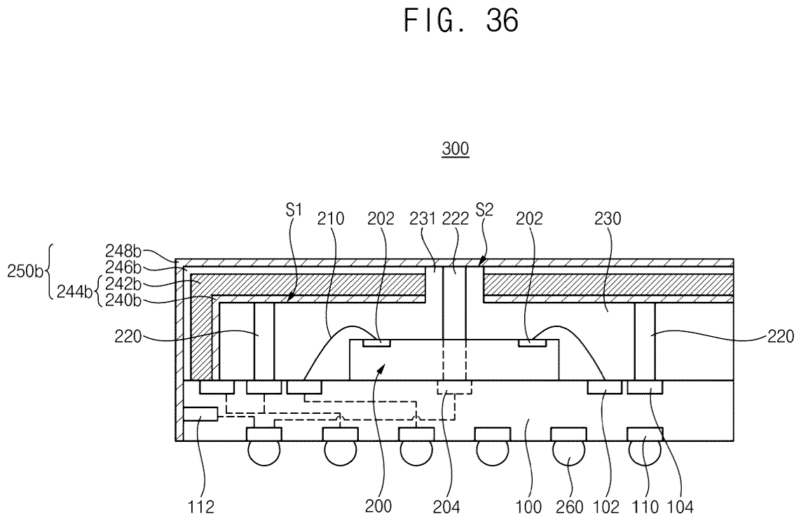

FIG. 36 is a cross-sectional view illustrating a semiconductor package according to one or more example embodiments.

The semiconductor package 300 shown in FIG. 36 is substantially identical to the semiconductor package shown in FIG. 25, except for the capacitor.

Referring to FIG. 36, a stacked structure of the lower electrode structure 244b and the dielectric layer 246b of the capacitor 250b may be arranged on the first upper surface and some of the four sidewalls of the sealing member 230. Thus, the capacitor 250b may not be arranged on remaining sidewalls of the sealing member 230. The lower electrode structure 244b may include a first metal layer 240b and a second metal layer 242b.

The upper electrode 248b may cover the upper surface of the protrusion 131 of the dielectric layer 246b and the sealing member 230, and a portion of sidewalls of the package substrate 100 contacting the dielectric layer 246b.

The lower electrode structure 244b and the dielectric layer 246b may not formed on a portion of the sidewalls of the sealing member 230 and a portion of sidewalls of the package substrate 100, and thus the portions of one or more sidewalls of the sealing member 230 and the package substrate 100 may be exposed on outer sidewalls of the semiconductor package.

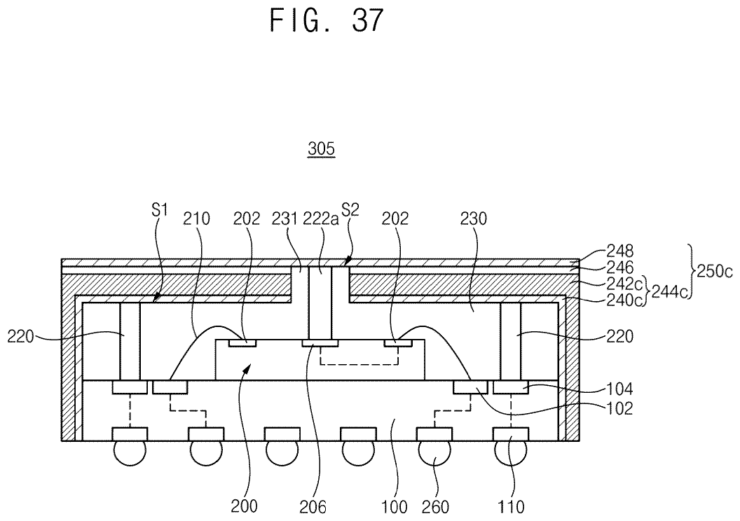

FIG. 37 is a cross-sectional view illustrating a semiconductor package according to one or more example embodiments.

The semiconductor package shown in FIG. 37 is substantially identical to the semiconductor package shown in FIG. 20, except for the capacitor.

Referring to FIG. 37, the lower electrode structure 244c of the capacitor 250c may include a first metal layer 240c and a second metal layer 242c. In one or more example embodiments, the first metal layer 240c may include stainless steel (SUS), and the second metal layer 242c may include copper.

The lower electrode structure 244c may be disposed on the first upper surface of the sealing member 230, the sidewall of the sealing member 230 and the sidewall of the package substrate 100. For example, the lower electrode structure 244c may surround the first upper surface of the sealing member 230, an entire sidewall of the sealing member 230, and an entire sidewall of the package substrate 100. In one or more example embodiments, the second metal layer 242c may be formed by a sputtering process. The second metal layer 242c may be formed relatively thicker on a flat surface in a horizontal direction than on a surface in a vertical direction. In one or more example embodiments, the second metal layer 242c formed on the first upper surface of the sealing member 230 may be thicker than the second metal layer 242c formed on the entire sidewall of the sealing member 230 and the entire sidewall of the package substrate 100.

The dielectric layer 246 may be disposed on a portion of a surface of the lower electrode structure 244c. The dielectric layer 246 may be disposed only on an upper surface of the lower electrode structure 244c formed on an upper surface of the sealing member 230. Therefore, the dielectric layer 246 may only be positioned on the flat surface in the horizontal direction of the lower electrode structure 244c.

The upper electrode 248 may be positioned on the dielectric layer 246, the second upper surface S2 of the sealing member 230, and the second conductive post 222, so as to cover the surface of the dielectric layer 246, the second upper surface S2 of the sealing member 230, and the upper surface of the second conductive post 222.

Because the dielectric layer 246 and the upper electrode 248 are positioned only on the upper surface of the lower electrode structure 244c formed on the upper surface of the sealing member 230, only the lower electrode structure 244c, the dielectric layer 246, and the upper electrode 248 formed on the upper surface of the sealing member 230 may function as a capacitor 250c. In addition, because the dielectric layer 246 and the upper electrode 248 may not be disposed on the lower electrode structure 244c formed on the sidewall of the sealing member 230 and the sidewall of the package substrate 100, the lower electrode structure 244c formed on the sidewall of the sealing member 230 and the sidewall of the package substrate 100 may not function as the lower electrode of the capacitor 250c. That is, an effective capacitor may be disposed only on an upper surface of the semiconductor package 305. The lower electrode structure 244c formed on the sidewall of the sealing member 230 and the sidewall of the package substrate 100 may serve as a protect layer of the semiconductor package 305. In addition, because the effective capacitor is disposed only on the upper surface of the semiconductor package 305 and is not disposed on the sidewall portion of the semiconductor package 305, a portion where the dielectric layer 246 and the upper electrode 248 are bent in the vertical direction may not occur. Accordingly, defects such as the dielectric layer 346 being cut off at a bending portion of a boundary between the upper surface and the sidewall portion of the semiconductor package 305 may not occur, and accordingly, the defects of the capacitor 250c may be reduced.

In FIG. 37, the first conductive post 220 may be connected to the lower electrode structure 244c, similarly to that described with reference to FIG. 20. In addition, a second conductive post 222a may be connected to the upper electrode 248. A lower surface of the first conductive post 220 may contact the second pad pattern 104 on the package substrate 100. The second conductive post 222a may be spaced apart from the lower electrode structure 244c, and the upper surface of the second conductive post 222a may contact the upper electrode 248. The second conductive post 222a may extend to the upper surface of the semiconductor chip 200 passing through the sealing member 230. In addition, the second conductive post 222a may be electrically connected to the first pad pattern 102, and the first pad pattern 102 and the internal wirings of the package substrate 100 may be electrically connected by the conductive wire 210 formed by a wire bonding process. The lower surface of the second conductive post 222a may contact the fifth pad pattern 206 on the semiconductor chip 200.

However, the electrical connection of the lower electrode structure and the electrical connection of the upper electrode may not be limited thereto. The electrical connection of the lower electrode structure and the electrical connection of the upper electrode may be implemented as in each of the embodiments described above. That is, in the other embodiments described above, as in FIG. 37, the lower electrode structure of the capacitor may be disposed on the first upper surface of the sealing member, the sidewall of the sealing member, and the sidewall of the package substrate, and the dielectric layer and the upper electrode may be disposed only on the upper surface of the lower electrode structure formed on the upper surface of the sealing member.

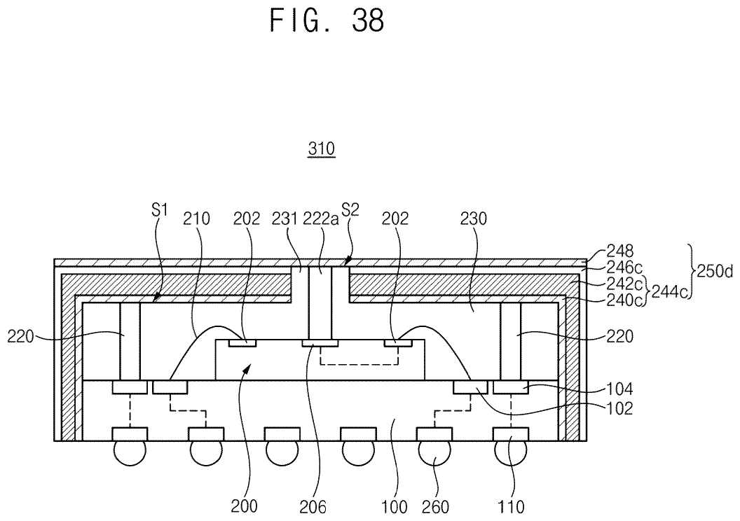

FIG. 38 is a cross-sectional view illustrating a semiconductor package according to exemplary embodiments.

The semiconductor package illustrated in FIG. 38 is substantially identical to the semiconductor package illustrated in FIG. 37, except for a dielectric layer of a capacitor.

Referring to FIG. 38, the lower electrode structure 244c may be disposed on the first upper surface S1 of the sealing member 230, sidewalls of the sealing member 230, and sidewalls of the package substrate 100.

The dielectric layer 246c may cover an entire upper surface of the lower electrode structure 244c. The dielectric layer 246 may be disposed on the first upper surface S1 of the sealing member 230, the sidewalls of the sealing member 230, and the sidewalls of the package substrate 100.

The upper electrode 248 may be disposed on a portion of the surface of the dielectric layer 246c. The upper electrode 248 may be disposed only on the dielectric layer 246c formed on an upper surface of the sealing member 230. Therefore, the upper electrode 248 may be positioned only on a flat surface in the horizontal direction of the dielectric layer 246c. Because the upper electrode 248 is positioned only on an upper surface of the dielectric layer 246c formed on the upper surface of the sealing member 230, only the lower electrode structure 244c, the dielectric layer 246c, and the upper electrode 248 formed on the upper surface of the sealing member 230 may function as a capacitor 250d. That is, in the case of the semiconductor package illustrated in FIG. 38, an effective capacitor may be Disposed only on an upper surface of the semiconductor package 310.

While the present inventive concepts have been shown and described with reference to one or more example embodiments thereof, it will be understood by those of ordinary skill in the art that various changes in form and details may be made thereto without departing from the scope of the present inventive concepts as set forth by the following claims.

What is claimed is:

1. A semiconductor package, comprising:
a package substrate;
a semiconductor chip on the package substrate;
conductive wires configured to be electrically connected to the semiconductor chip and the package substrate;
a sealing member on the package substrate, the semiconductor chip, and the conductive wires;
external connection members on a lower surface of the package substrate;
a capacitor on at least an upper surface of the sealing member, the capacitor comprising a lower electrode structure, a dielectric layer, and an upper electrode sequentially stacked;
a first conductive post configured to be electrically connected to at least one of the external connection members, the first conductive post in the sealing member and comprising an upper surface in contact with the lower electrode structure; and
a second conductive post configured to be electrically connected to at least one of the external connection members, the second conductive post in the sealing member and spaced apart from the lower electrode structure, and comprising an upper surface in contact with the upper electrode,
wherein at least one of the first conductive post or the second conductive post is spaced apart from the conductive wires.

2. The semiconductor package of claim 1, wherein the second conductive post extends through the lower electrode structure.

3. The semiconductor package of claim 1, wherein a lower surface of the first conductive post contacts an upper surface of the package substrate, and a lower surface of the second conductive post contacts an upper surface of the package substrate.

4. The semiconductor package of claim 1, wherein at least one of a lower surface of the first conductive post or a lower surface of the second conductive post contacts the upper surface of the semiconductor chip.

5. The semiconductor package of claim 1, wherein a lower surface of the first conductive post contacts an upper surface of the package substrate, a lower surface of the second conductive post contacts an upper surface of the semiconductor chip, and a lower surface of the second conductive post is configured to be electrically connected to at least one of the conductive wires.

6. The semiconductor package of claim 1, wherein the first conductive post comprises a plurality of first conductive posts comprising, respectively, a plurality of first lower surfaces, one or more of the plurality of first lower surfaces in contact with an upper surface of the package substrate, and another one or more of the plurality of first lower surfaces in contact with an upper surface of the semiconductor chip, and
wherein the second conductive post comprises a plurality of second conductive posts, respectively, a plurality of second lower surfaces, one or more of the plurality of second lower surfaces in contact with the upper surface of the package substrate, and another one or more of the plurality of second lower surfaces in contact with the upper surface of the semiconductor chip.

7. The semiconductor package of claim 1, wherein the first conductive post and the second conductive post are connected to different ones of the external connection members, respectively.

8. The semiconductor package of claim 1, wherein an upper portion of the sealing member comprises a protrusion and a recessed portion, the protrusion facing at least a portion of an upper surface of the semiconductor chip, and
wherein the lower electrode structure is on sidewalls of the protrusion.

9. The semiconductor package of claim 8, wherein:
the first conductive post penetrates downwardly from a surface of the recessed portion, and
the second conductive post penetrates downwardly from an upper surface of the protrusion.

10. The semiconductor package of claim 8,
wherein the lower electrode structure and the dielectric layer are on a surface of the recessed portion and the first conductive post, and
wherein the upper electrode is on the protrusion, the dielectric layer, and the second conductive post.

11. The semiconductor package of claim 8,
wherein the lower electrode structure and the dielectric layer are on a surface of the recessed portion, at least a portion of a sidewall of the sealing member, and the first conductive post, and
wherein the upper electrode is on the protrusion, the dielectric layer, the upper surface of the second conductive post, and at least a portion of a sidewall of the package substrate.

12. The semiconductor package of claim 1,
wherein the upper electrode overlaps, in plan view, an entirety of an upper surface of the package substrate, and
wherein the package substrate, the sealing member, the lower electrode structure, the dielectric layer, and the upper electrode are exposed together on at least one sidewall of the semiconductor package.

13. The semiconductor package of claim 1, wherein:
the lower electrode structure comprises a first metal layer comprising stainless steel and a second metal layer comprising copper,
the upper electrode comprises stainless steel, and
the dielectric layer comprises one or more of silicon oxide, silicon nitride, silicon oxynitride, titanium oxide, tantalum oxide, hafnium oxide, zirconium oxide, or polyimide PI.

14. A semiconductor package, comprising:
a package substrate comprising a first pad pattern, a second pad pattern, and a third pad pattern on an upper surface thereof;
a semiconductor chip on the package substrate, an upper surface of the semiconductor chip comprising a fourth pad pattern;
a conductive wire configured to be electrically connected to the first pad pattern and the fourth pad pattern;
a sealing member on the package substrate, the semiconductor chip, and the conductive wire;
a capacitor comprising a lower electrode structure, a dielectric layer, and an upper electrode sequentially stacked on an upper surface of the sealing member;
a first conductive post in the sealing member and spaced apart from the semiconductor chip, the first conductive post extending upwardly from the second pad pattern and in contact with the lower electrode structure; and
a second conductive post in the sealing member and spaced apart from the semiconductor chip, the second conductive post extending upwardly from the third pad pattern and in contact with the upper electrode, and spaced apart from the lower electrode structure,
wherein at least one of the first conductive post or the second conductive post is spaced apart from the conductive wire.

15. The semiconductor package of claim 14, further comprising external connection members configured to be electrically connected, respectively, to the first pad pattern, the second pad pattern, and the third pad pattern, and
wherein the external connection members are on a lower surface of the package substrate.

16. The semiconductor package of claim 14, wherein an upper portion of the sealing member comprises a protrusion and a recessed portion,
wherein the lower electrode structure and the dielectric layer are on the recessed portion and the first conductive post, and
wherein the upper electrode is on the protrusion, the dielectric layer, and the second conductive post.

17. The semiconductor package of claim 14, wherein an upper portion of the sealing member comprises a protrusion and a recessed portion,
wherein the lower electrode structure and the dielectric layer are on the recessed portion, at least a portion of one or more sidewalls of the sealing member, and the first conductive post, and
wherein the upper electrode is on the protrusion, the dielectric layer, the upper surface of the second conductive post, and at least a portion of one or more sidewalls of the package substrate.

18. The semiconductor package of claim 17, further comprising:
an external connection member on a lower surface of the package substrate; and
a conductive pattern exposed by the one or more sidewalls of the package substrate, wherein the upper electrode contacts the conductive pattern.

19. The semiconductor package of claim 15, further comprising:
a fifth pad pattern and a sixth pad pattern on the upper surface of the package substrate,
a third conductive post in the sealing member, the third conductive post extending upward from the fifth pad pattern and in contact with the lower electrode structure; and
a fourth conductive post in the sealing member, the fourth conductive post extending upward from the sixth pad pattern and in contact with the upper electrode and spaced apart from the lower electrode structure.

20. A semiconductor package, comprising:
a package substrate comprising a first pad pattern and a second pad pattern on an upper surface thereof;
a semiconductor chip on the package substrate, an upper surface of the semiconductor chip comprising a third pad pattern and a fourth pad pattern;
a conductive wire configured to be electrically connected to the first pad pattern and the third pad pattern;
a sealing member on the package substrate, the semiconductor chip, and the conductive wire;
a capacitor comprising a lower electrode structure, a dielectric layer, and an upper electrode sequentially stacked on at least an upper surface of the sealing member;
a first conductive post in the sealing member and spaced apart from the semiconductor chip, the first conductive post extending upwardly from the second pad pattern and in contact with the lower electrode structure; and
a second conductive post in the sealing member, the second conductive post extending upwardly from the fourth pad pattern and in contact with the upper electrode, and spaced apart from the lower electrode structure,
wherein at least one of the first conductive post or the second conductive post is spaced apart from the conductive wire.
